(19) United States
(12) Patent Application Publication
(10) Pub. No.: US 2026/0239797 A1
(43) Pub. Date: Aug. 13, 2026

(54) DISPLAY MODULE AND DISPLAY DEVICE

(71) Applicants: BEIJING BOE DISPLAY TECHNOLOGY CO., LTD., Beijing (CN); BOE TECHNOLOGY GROUP CO., LTD., Beijing (CN)

(72) Inventors: Huiyan Li, Beijing (CN); Miao Liu, Beijing (CN); Shixin Geng, Beijing (CN); Yikai Zhou, Beijing (CN); Lulu Wang, Beijing (CN); Xuefei Qin, Beijing (CN); Yu Zhang, Beijing (CN); Bochang Wang, Beijing (CN); Zhengyan Wan, Beijing (CN)

(21) Appl. No.: 19/475,010

(22) PCT Filed: Sep. 2, 2024
(86) PCT No.: PCT/CN2024/116348

§ 371 Date: Oct. 13, 2025

(30) Foreign Application Priority Data
Oct. 30, 2023 (CN) 202311422407.9

(51) Int. Cl. H10H 29/85

(52) U.S. Cl. CPC H10H 29/8506; H10H 29/8508

(57) ABSTRACT

Provided are a display module and a display device. The display module includes: a display panel; a backboard; a first circuit board disposed on a side of the backboard away from the display panel, extending in a first direction, and including first and second sides oppositely disposed in a second direction; a flexible clasper assembly including: a substrate, a first flexible clasper and a second flexible clasper used to clamp the first circuit board and allow displacement of the first circuit board within a first preset range in the second direction; a conductive foam disposed on a side of the backboard away from the display panel, at least one corner of the first circuit board is bonded to the backboard through the conductive foam, and the conductive foam allows displacement of the first circuit board within a second preset range in the first direction.

### CROSS REFERENCE TO RELATED APPLICATION(S)

This application is a Section 371 National Stage Application of International Application No. PCT/CN2024/116348 filed on Sep. 2, 2024, which claims priority of Chinese Application No. 202311422407.9 filed on Oct. 30, 2023, the whole contents of which are incorporated herein by reference in their entireties.

### TECHNICAL FIELD

The present disclosure relates to the field of display technologies, and in particular to a display module and a display device.

### BACKGROUND

With the development of display technologies, large-sized strip-shaped screens have gradually been integrated into people's daily lives and work. The large-sized strip-shaped screen is a narrow strip-shaped display with a long side length much greater than a short side length, such as an 86-inch strip-shaped screen that may have a long side length of up to 2.2 m and a short side length of only 0.36 m.

Due to structural characteristics, the large-sized strip-shaped screens are currently widely used in fields such as advertising and transportation (e.g., passenger guidance displays in subways and buses).

### SUMMARY

Provided are a display module and a display device.

According to a first aspect of the present disclosure, a display module is provided, including: a display panel including a display region and a peripheral region at least partially surrounding the display region, the peripheral region includes a display binding pad; a backboard disposed on a back side of the display panel; a first circuit board disposed on a side of the backboard away from the display panel, the first circuit board extends in a first direction, the first circuit board includes a first side and a second side oppositely disposed in a second direction, the first side is electrically connected to the display binding pad, the second side is configured to be electrically connected to a display driver chip, and the first direction intersects with the second direction; a flexible clasper assembly disposed on a side of the backboard away from the display panel, the flexible clasper assembly includes: a substrate, a first flexible clasper, and a second flexible clasper, the substrate is fixedly connected to the backboard, the first flexible clasper and the second flexible clasper are disposed on a side of the substrate away from the display panel, the first flexible clasper and the second flexible clasper are oppositely disposed in the second direction, and the first flexible clasper and the second flexible clasper are configured to clamp the first circuit board and allow a displacement of the first circuit board within a first preset range in the second direction; and a conductive foam disposed on a side of the backboard away from the display panel, at least one corner of the first circuit board is bonded to the backboard through the conductive foam, and the conductive foam allows a displacement of the first circuit board within a second preset range in the first direction.

According to embodiments of the present disclosure, a portion of the first circuit board clamped by the first flexible clasper and the second flexible clasper includes a first fixed portion; in a thickness direction of the display module, the first flexible clasper overlaps with the first fixed portion, and an overlapping region of the first flexible clasper and the first fixed portion has a first dimension in the second direction; in the thickness direction of the display module, the second flexible clasper overlaps with the first fixed portion, and an overlapping region of the second flexible clasper and the first fixed portion has a second dimension in the second direction; and the first fixed portion has a third dimension in the second direction, and a ratio of a sum of the first dimension and the second dimension to the third dimension is greater than or equal to ⅓ and less than or equal to ½.

According to embodiments of the present disclosure, the first dimension is set in a range of 3.5 mm to 4.5 mm, the second dimension is set in a range of 3.5 mm to 4.5 mm, and the third dimension is set in a range of 15 mm to 25 mm.

According to embodiments of the present disclosure, the first flexible clasper includes a first pressing portion and a first connecting portion, the first pressing portion is connected to the substrate through the first connecting portion, the second flexible clasper includes a second pressing portion and a second connecting portion, the second pressing portion is connected to the substrate through the second connecting portion, and in the thickness direction of the display module, the first pressing portion and the second pressing portion overlap with the first fixed portion; in the second direction, a first gap is provided between the first fixed portion and the first connecting portion, and a second gap is provided between the first fixed portion and the second connecting portion; in the thickness direction of the display module, a third gap is provided between the first fixed portion and any one of the first pressing portion or the second pressing portion; and any one of the first gap and the second gap is less than the third gap.

According to embodiments of the present disclosure, the first gap is set in a range of 0.1 mm to 0.2 mm, the second gap is set in a range of 0.1 mm to 0.2 mm, and the third gap is set in a range of 0.15 mm to 0.25 mm.

According to embodiments of the present disclosure, the first circuit board is electrically connected to the display binding pad through a plurality of chip-on-films, and the plurality of chip-on-films are arranged in the first direction; the display module includes a plurality of flexible clasper assemblies arranged in the first direction, at least one flexible clasper assembly is provided between at least two adjacent chip-on-films, a distance between two adjacent flexible clasper assemblies in the first direction is set in a range of 250 mm to 350 mm; and a dimension of the at least one flexible clasper assembly in the first direction is set in a range of 8 mm to 12 mm.

According to embodiments of the present disclosure, the display module further includes a front frame, the front frame includes a first frame body extending in a thickness direction of the display module, and in the second direction, the first frame body is located on a side of the backboard away from a center of the display module; in the second direction, a first distance is provided between the flexible clasper assembly and the first frame body, a second distance is provided between the backboard and the first frame body, and a third distance is provided between the display panel and the first frame body; and the first distance is greater than the second distance and less than the third distance.

According to embodiments of the present disclosure, the backboard includes a backboard main body, and a first bending portion and a second bending portion disposed on the backboard main body, and the first bending portion and the second bending portion are bent toward the display panel and are oppositely disposed in the second direction; in the second direction, the first circuit board is located between the first bending portion and the second bending portion, and a distance between the first bending portion and the first circuit board is less than a distance between the second bending portion and the first circuit board; and in a thickness direction of the display module, the first flexible clasper overlaps with the first bending portion.

According to embodiments of the present disclosure, the second side of the first circuit board includes a first corner and a second corner oppositely disposed in the first direction, at least one of the first corner and the second corner includes an exposed metal region, and the conductive foam at least partially covers the exposed metal region.

According to embodiments of the present disclosure, a dimension of the conductive foam in the first direction is set in a range of 4 mm to 6 mm, a dimension of the conductive foam in the second direction is set in a range of 4 mm to 6 mm, and a thickness of the conductive foam is set in a range of 1 mm to 3 mm.

According to embodiments of the present disclosure, the display module further includes an optical film and a plastic frame, the optical film is disposed between the backboard and the display panel, the optical film includes a third side and a fourth side oppositely disposed in the first direction, and a lug hole is provided on the third side; the plastic frame includes a second frame body extending in a thickness direction of the display module, and the second frame body is located on a side of the third side of the optical film away from a center of the optical film; and the plastic frame further includes a lug structure disposed on the second frame body, the lug structure extends toward the optical film, in the thickness direction of the display module, the lug structure overlaps with the lug hole, and in an overlapping region of the lug structure and the lug hole, the lug structure passes through the lug hole.

According to embodiments of the present disclosure, a lug protrusion is further fixedly provided on the third side, the lug protrusion is located on a side of the lug hole away from the center of the optical film, and the display module further includes an auxiliary fixing tape; the backboard includes a backboard main body, and a third bending portion and a fourth bending portion disposed on the backboard main body, and the third bending portion and the fourth bending portion are bent toward the display panel and are oppositely disposed in the first direction; a side of the third bending portion away from a center of the display module is flush with the fourth side of the optical film; and the auxiliary fixing tape includes a winding portion and a first bonding portion, the winding portion passes through the lug hole and is wound around the lug protrusion, and the first bonding portion is bonded to the fourth bending portion.

According to embodiments of the present disclosure, a first groove is provided on a side of the fourth bending portion close to the display panel, the first groove is recessed toward the backboard main body, and the lug protrusion is lapped in the first groove.

According to embodiments of the present disclosure, the second frame body is located on a side of the fourth bending portion away from the center of the display module; and the first bonding portion is bonded to a surface of the fourth bending portion facing the second frame body, and a gap is provided between the first bonding portion and the second frame body.

According to embodiments of the present disclosure, the auxiliary fixing tape further includes an intermediate portion between the winding portion and the first bonding portion, and an end of the winding portion is bonded to the intermediate portion after bypassing an edge of the lug hole; and the fourth bending portion includes a second groove recessed toward a side away from the second frame body, and the end of the winding portion is at least partially located in the second groove.

According to embodiments of the present disclosure, a dimension of the first bonding portion in the second direction is greater than a dimension of the intermediate portion in the second direction, a transition corner is provided at a junction of the first bonding portion and the intermediate portion, and the transition corner includes an arc-shaped corner.

According to embodiments of the present disclosure, the first bonding portion is bonded to two adjacent side surfaces of the fourth bending portion.

According to embodiments of the present disclosure, the optical film includes a composite prism and a diffuser; in the first direction, the diffuser includes a first surface and a second surface oppositely disposed in a thickness direction of the diffuser, the first surface is located on a side of the second surface close to the composite prism, and a first light-shielding structure is provided on the first surface; and the first surface includes a lug side and an opposite lug side oppositely disposed in the first direction, the lug hole is located on the lug side, and the first light-shielding structure is located on the opposite lug side.

According to embodiments of the present disclosure, a dimension of the first light-shielding structure in the first direction is set in a range of 2 mm to 4 mm.

According to embodiments of the present disclosure, the first light-shielding structure includes a black tape or a printed black border.

According to embodiments of the present disclosure, the optical film includes a single prism and a diffuser, the lug hole penetrates the single prism and the diffuser, and a thermal shrinkage rate of the single prism is the same as a thermal shrinkage rate of the diffuser.

According to embodiments of the present disclosure, the backboard includes a fifth side and a sixth side oppositely disposed in the second direction, the flexible clasper assembly is located on the fifth side, and the display module further includes: a light source assembly disposed on the sixth side of the backboard, the light source assembly extends in the first direction, a light-emitting direction of the light source assembly intersects with a thickness direction of the display module, and the light source assembly includes a first end and a second end oppositely disposed in the first direction; and a support foam extending in the first direction, the support foam includes a third end and a fourth end oppositely disposed in the first direction, the first end is flush with the third end, and the second end is flush with the fourth end.

According to embodiments of the present disclosure, the display module further includes a light guide plate and a reflective sheet; the reflective sheet includes a third surface and a fourth surface oppositely disposed in a thickness direction of the reflective sheet, the third surface is located on a side of the fourth surface close to the light guide plate, and a second light-shielding structure is provided on the third surface; and the third surface includes a seventh side and an eighth side oppositely disposed in the second direction, the eighth side is located on a side of the seventh side close to the light source assembly, and the second light-shielding structure is located on the eighth side.

According to embodiments of the present disclosure, a dimension of the second light-shielding structure in the first direction is set in a range of 1 mm to 3 mm, and a dimension of the second light-shielding structure in the second direction is set in a range of 2 mm to 4 mm.

According to embodiments of the present disclosure, the display module further includes a third light-shielding structure, and the third light-shielding structure is integrally connected with the second light-shielding structure; and the backboard includes a fifth surface and a sixth surface oppositely disposed in a thickness direction of the backboard, the fifth surface is located on a side of the sixth surface close to the display panel, and the third light-shielding structure is located on the sixth surface.

According to embodiments of the present disclosure, a dimension of the third light-shielding structure in the first direction is set in a range of 3 mm to 5 mm.

According to embodiments of the present disclosure, the display module includes a light source assembly and a plastic frame, the light source assembly includes a plurality of light-emitting devices, the plastic frame includes a plurality of sub-frames, and the plurality of sub-frames include a first sub-frame and a second sub-frame oppositely disposed in the first direction, and a plurality of third sub-frames located between the first sub-frame and the second sub-frame; each of the third sub-frames includes a first splicing portion and a second splicing portion oppositely disposed in the first direction, and the first splicing portion of one of two adjacent third sub-frames in the first direction is spliced with the second splicing portion of the other of the two adjacent third sub-frames in the first direction; the first splicing portion includes a first sidewall, the second splicing portion includes a second sidewall, each of the first sidewall and the second sidewall is located on a side of the light source assembly close to a center of the display module, a first barrier is provided on a side of the first sidewall away from the center of the display module, and a second barrier is provided on a side of the second sidewall away from the center of the display module; and the first barrier and the second barrier overlap in a thickness direction of the display module, and an overlapping region of the first barrier and the second barrier overlaps with at least one of the light-emitting devices in the thickness direction of the display module.

According to embodiments of the present disclosure, the overlapping region of the first barrier and the second barrier has a first design dimension in the first direction, and the first design dimension is greater than or equal to 1 mm to 2.5 mm.

According to embodiments of the present disclosure, the display module further includes a front frame, and in an overlapping region of two adjacent third sub-frames, a limiting structure is filled in a gap between one of the two adjacent third sub-frames and the front frame.

According to a second aspect of the present disclosure, a display device is provided, including the display module described above.

### BRIEF DESCRIPTION OF THE DRAWINGS

The above contents and other objectives, features, and advantages of the present disclosure will be more apparent through the following descriptions of embodiments of the present disclosure with reference to the accompanying drawings, in which:

FIG. 1 and FIG. 2 schematically show schematic diagrams of a display module in a comparative example;

FIG. 3 schematically shows a schematic diagram of a connection between a first circuit board and a display panel in a comparative example;

FIG. 4 schematically shows a schematic diagram of a connection between a first circuit board and a backboard in a comparative example;

FIG. 5 and FIG. 6 schematically show schematic diagrams of a display module in embodiments of the present disclosure;

FIG. 7 schematically shows an exploded view of a display module according to embodiments of the present disclosure;

FIG. 8 schematically shows a plan view of a display panel according to embodiments of the present disclosure;

FIG. 9 schematically shows a schematic diagram of a connection between a first circuit board and a display panel according to embodiments of the present disclosure;

FIG. 10 schematically shows a schematic diagram of a connection between a first circuit board and a backboard according to embodiments of the present disclosure;

FIG. 11 and FIG. 12 schematically show cross-sectional views taken along section line BB′ in FIG. 10;

FIG. 13 schematically shows a schematic diagram of position A in FIG. 10;

FIG. 14 schematically shows a plan view of an optical film in embodiments of the present disclosure;

FIG. 15 schematically shows a cross-sectional view taken along section line CC′ in FIG. 5;

FIG. 16A schematically shows a schematic diagram of an auxiliary fixing tape in embodiments of the present disclosure;

FIG. 16B schematically shows a schematic diagram of a first groove in embodiments of the present disclosure;

FIG. 17 schematically shows a schematic diagram of an auxiliary fixing tape after being unfolded in embodiments of the present disclosure;

FIG. 18 and FIG. 19 schematically show schematic diagrams of a first light-shielding structure in embodiments of the present disclosure;

FIG. 20 schematically shows a schematic diagram of light leakage caused by shrinkage of a composite prism and a diffuser;

FIG. 21 schematically shows a schematic diagram of a light source assembly and support foam in embodiments of the present disclosure;

FIG. 22 schematically shows a cross-sectional view taken along section line DD′ in FIG. 21;

FIG. 23 schematically shows a schematic diagram of a reflective sheet exposed after shrinkage of a light guide plate in embodiments of the present disclosure;

FIG. 24 schematically shows a cross-sectional view taken along section line EE′ in FIG. 5;

FIG. 25 schematically shows a cross-sectional view taken along section line FF′ in FIG. 5;

FIG. 26 schematically shows a schematic diagram of a barrier structure in embodiments of the present disclosure;

FIG. 27 schematically shows a schematic diagram of light shielding by a barrier in embodiments of the present disclosure;

FIG. 28 schematically shows a schematic diagram of a gap between a third sub-frame and a front frame in embodiments of the present disclosure;

FIG. 29 schematically shows a schematic diagram of a limiting structure in embodiments of the present disclosure; and FIG. 30 schematically shows a second exploded view of a display module in embodiments of the present disclosure.

### DETAILED DESCRIPTION OF EMBODIMENTS

In order to make objectives, technical solutions and advantages of the present disclosure clearer, the technical solutions in embodiments of the present disclosure will be described clearly and completely with reference to the accompanying drawings. Obviously, the described embodiments are some, but not all of embodiments of the present disclosure. Based on the described embodiments of the present disclosure, all other embodiments obtained by those skilled in the art without any creative work fall within the scope of protection of the present disclosure.

It should be noted that in the accompanying drawings, a size and a relative size of an element may be enlarged for the purpose of clarity and/or description. As such, the size and the relative size of each element are not necessarily limited to those shown in the drawings. In the specification and the accompanying drawings, the same or similar reference numerals indicate the same or similar components.

When an element is described as being “on”, “connected to” or “coupled to” another element, the element may be directly on, directly connected to or directly coupled to the another element, or there may be an intermediate element. However, when an element is described as being “directly on”, “directly connected to” or “directly coupled to” another element, there is no intermediate element. Other terms and/or expressions used to describe a relationship between elements should be interpreted in a similar way, for example, “between . . . ” versus “directly between . . . ”, “adjacent” versus “directly adjacent” or “on . . . ” versus “directly on . . . ”, etc. In addition, a term “connection” may refer to a physical connection, an electrical connection, a communication connection and/or a fluid connection. In addition, an X axis, a Y axis and a Z axis are not limited to three axes of a rectangular coordinate system, and may be interpreted in a broader sense. For example, the X axis, the Y axis and the Z axis may be perpendicular to each other, or may represent different directions that are not perpendicular to each other. For the purpose of the present disclosure, “at least one of X, Y and Z” and “at least one selected from a group consisting of X, Y and Z” may be interpreted as only X, only Y, only Z, or any combination of two or more of X, Y and Z such as XYZ, XY, YZ and ZZ. A term “and/or” as used herein includes any and all combinations of one or more of listed related items.

It should be noted that although terms “first”, “second”, etc. may be used here to describe various components, members, elements, regions, layers and/or portions, the components, members, elements, regions, layers and/or portions should not be limited by the terms. Rather, the terms are used to distinguish one component, member, element, region, layer and/or portion from another. Thus, for example, a first component, a first member, a first element, a first region, a first layer and/or a first portion discussed below may be referred to as a second component, a second member, a second element, a second region, a second layer and/or a second portion without departing from the teachings of the present disclosure.

For the convenience of description, spatial relational terms such as “upper”, “lower”, “left”, “right”, etc. may be used here to describe a relationship between one element or feature and another element or feature as shown in the drawings. It should be understood that the spatial relational terms are intended to cover different orientations of a device in use or operation other than those described in the drawings. For example, if the device in the drawing is upside down, an element described as “below” or “under” another element or feature may be oriented as “on” or “above” the another element or feature.

Terms “substantially”, “approximately”, “about”, “roughly” and other similar terms used herein are used as approximate terms rather than as terms of degree, and they are intended to explain an inherent deviation of a measured value or calculated value that will be recognized by those skilled in the art. In consideration of factors such as a process fluctuation, a measurement problem and an error (i.e., a limitation of a measurement system) related to a measurement of a particular quantity, “approximately” or “about” as used here includes a stated value and indicates that a particular value determined by those skilled in the art is within an acceptable deviation range. For example, “approximately” may mean that a value is within one or more standard deviations, or within ±30%, ±20%, ±10%, and ±5% of the stated value.

Those skilled in the art should understand that, unless otherwise specified, an expression “height” or “thickness” used herein refers to a size perpendicular to a surface of each film of a display module, that is, a size in a light emitting direction of the display module, or a size in a normal direction of the display module.

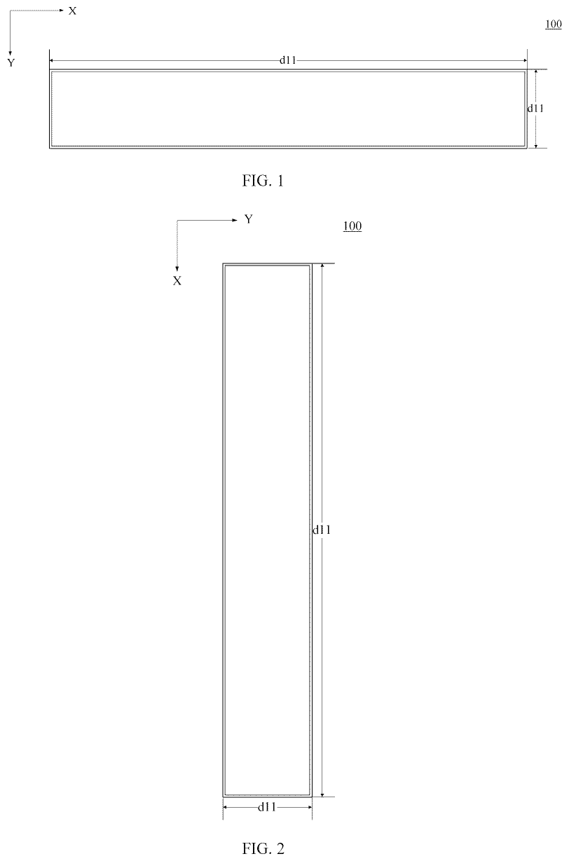

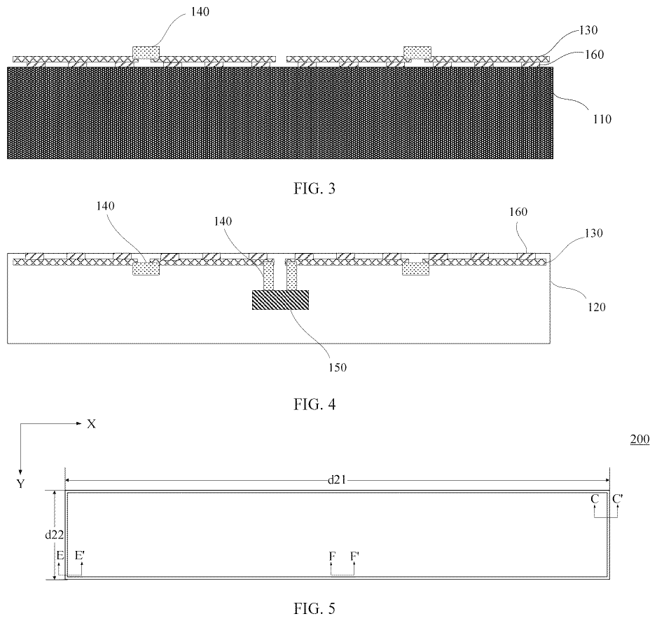

In a comparative example, a display module 100 is provided. FIG. 1 and FIG. 2 schematically show schematic diagrams of a display module in a comparative example, where FIG. 1 schematically shows the display module in a horizontal orientation, and FIG. 2 schematically shows the display module in a vertical orientation. Referring to FIG. 1 and FIG. 2, the display module 100 in this comparative example is a large-sized strip-shaped display module 100. The display module 100 has two short sides oppositely disposed in a first direction X and two long sides oppositely disposed in a second direction Y. A length d11 of the long side of the display module 100 is 2.2 m, and a length d12 of the short side of the display module 100 is 0.36 m.

FIG. 3 schematically shows a schematic diagram of a connection between a first circuit board and a display panel in a comparative example, and FIG. 4 schematically shows a schematic diagram of a connection between a first circuit board and a backboard in a comparative example.

Referring to FIG. 3 and FIG. 4, the display module 100 in this comparative example includes a display panel 110, a backboard 120, and a first circuit board 130. The backboard 120 is disposed on a back side of the display panel 110, and the first circuit board 130 is disposed on a side of the backboard 120 away from the display panel 110. A side of the first circuit board 130 is electrically connected to the display panel 110, and the other side of the first circuit board 130 is electrically connected to a display driver chip 150 through a connection structure 140, thereby transmitting an electrical signal on the display driver chip 150 to the display panel 110. For example, a side of the first circuit board 130 may be electrically connected to the display panel 110 through a flexible connector such as a COF (chip-on-film) 160, etc.

In this comparative example, the display module 100 adopts a “horizontal display” mode. The “horizontal display” mode may mean that, the display module 100 is in a state of horizontal orientation as shown in FIG. 1 when viewed by human eyes. Referring to FIG. 1, in the “horizontal display” mode, the two long sides of the display module 100 extend in a horizontal direction in FIG. 1, and the two short sides of the display module 100 extend in a vertical direction in FIG. 1.

In order to expand application scenarios of the display module 100, it is desirable that the display module 100 may have more display modes. For example, a “vertical display” mode is added to the display module 100, where the “vertical display” mode may mean that, the display module 100 is in a state of vertical orientation as shown in FIG. 2 when viewed by the human eyes. Referring to FIG. 2, in the “vertical display” mode, the two long sides of the display module 100 extend in a vertical direction in FIG. 2, and the two short sides of the display module 100 extend in a horizontal direction in FIG. 2.

In this comparative example, the first circuit board 130 is connected to the backboard 120 through a rigid fastener (e.g., a screw or a rigid snap-fit). Due to a large size of the display panel 110, in a practical application, the display panel 110 sinks to a certain extent under an influence of gravity. Since the first circuit board 130 is connected to the backboard 120 through the rigid fastener, the sinking of the display panel 110 may cause the COF 160 between the first circuit board 130 and the display panel 110 to be pulled.

Furthermore, since the display module 100 is a large-sized strip-shaped display module 100, and a length of its long side is much greater than a length of its short side, the display panel 110 sinks to a greater extent in the “vertical display” mode than in the “horizontal display” mode. The severe pulling on the COF 160 may lead to an obvious black-state light leakage problem in the display module.

In view of this, embodiments of the present disclosure provide a display module, including: a display panel, a backboard, a first circuit board, a flexible clasper assembly, and conductive foam. The display panel includes a display region and a peripheral region at least partially surrounding the display region. The display region includes a plurality of pixel units arranged in an array in a first direction and a second direction, where the first direction intersects with the second direction. The peripheral region includes a display binding pad. The backboard is disposed on a back side of the display panel. The first circuit board is disposed on a side of the backboard away from the display panel, where the first circuit board extends in the first direction, the first circuit board includes a first side and a second side oppositely disposed in the second direction, the first side is electrically connected to the display binding pad, the second side is used to be electrically connected to a display driver chip. The flexible clasper assembly is disposed on a side of the backboard away from the display panel, where the flexible clasper assembly includes: a substrate, a first flexible clasper, and a second flexible clasper, the substrate is fixedly connected to the backboard, the first flexible clasper and the second flexible clasper are disposed on a side of the substrate away from the display panel, the first flexible clasper and the second flexible clasper are oppositely disposed in the second direction, and the first flexible clasper and the second flexible clasper are used to clamp the first circuit board and allow a displacement of the first circuit board within a first preset range in the second direction. The conductive foam is disposed on a side of the backboard away from the display panel, where at least one corner of the first circuit board is bonded to the backboard through the conductive foam, and the conductive foam allows a displacement of the first circuit board within a second preset range in the first direction.

By the above-mentioned method, the first circuit board may have a certain degree of freedom of displacement in both the first direction and the second direction. In this way, no matter whether in the “horizontal display” mode or the “vertical display” mode, when the display panel sinks, the first circuit board may also move accordingly, thereby alleviating pulling on the COF. At the same time, through cooperation of the flexible clasper assembly and the conductive foam, the first circuit board may be allowed to displace to a greater extent in the first direction (compared to a displacement in the second direction), thereby reducing or even eliminating a problem of the severe pulling on the COF in the “vertical display” mode, and further improving the black-state light leakage problem caused thereby.

The display module according to embodiments of the present disclosure will be described in detail below with reference to FIG. 5 to FIG. 13.

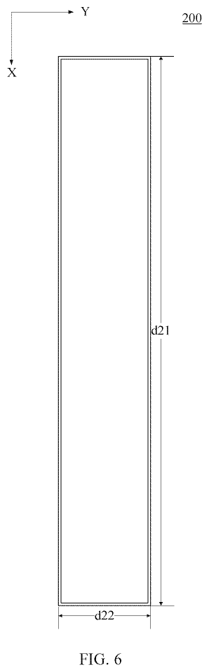

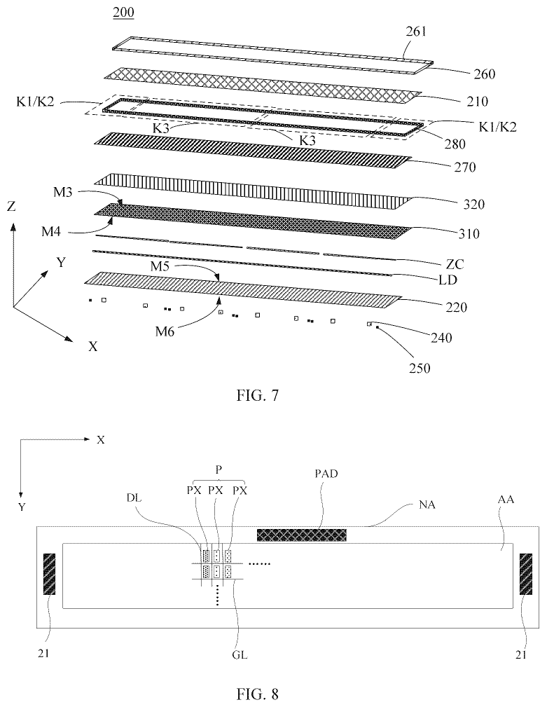

FIG. 5 and FIG. 6 schematically show schematic diagrams of a display module in embodiments of the present disclosure. Referring to FIG. 5 and FIG. 6, a display module 200 in embodiments of the present disclosure may be a large-sized strip-shaped display module 200. The display module has two short sides oppositely disposed in the first direction X and two long sides oppositely disposed in the second direction Y, where the first direction X intersects with the second direction Y. The first direction X may be a horizontal direction in FIG. 5, and the second direction Y may be a vertical direction in FIG. 5, that is, the first direction X and the second direction Y are perpendicular to each other.

In embodiments of the present disclosure, a length of the long side of the display module is much greater than a length of the short side of the display module. For example, a length d21 of the long side of the display module is in a range of 2 m to 2.4 m, such as 2.2 m; and a length d22 of the short side of the display module is in a range of 0.33 m to 0.39 m, such as 0.36 m.

In embodiments of the present disclosure, the display module 200 may include both a “horizontal display” mode and a “vertical display” mode. For specific contents of the “horizontal display” mode and the “vertical display” mode, reference may be made to the above-mentioned examples, which will not be repeated here.

FIG. 7 schematically shows an exploded view of a display module according to embodiments of the present disclosure, and FIG. 8 schematically shows a plan view of a display panel according to embodiments of the present disclosure.

Referring to FIGS. 7 and 8, the display module in embodiments of the present disclosure includes a display panel 210, and the display panel 210 includes: a display region AA and a peripheral region NA located on at least one side of the display region AA.

The display region AA may have various shapes. For example, the display region AA may be set in various shapes such as a polygon (e.g., a rectangle) with a closed shape including a straight edge, a circle or ellipse with a curved edge, or a semicircle or semi-ellipse with straight and curved edges. In embodiments of the present disclosure, the display region AA is set as a quadrilateral region with straight edges. It should be understood that, the embodiments are merely exemplary embodiments of the present disclosure, rather than limitations to the present disclosure.

The display panel 210 may further include a base substrate 200, and a plurality of pixel units P located in the display region AA on the base substrate 200. The plurality of pixel units P may be arranged in an array in the first direction X and the second direction Y. Each pixel unit P may include a plurality of sub-pixels PX. For example, the pixel unit P may include a first sub-pixel, a second sub-pixel, and a third sub-pixel. For example, the first sub-pixel, the second sub-pixel, and the third sub-pixels may be set as a red sub-pixel, a green sub-pixel, and a blue sub-pixel, respectively. However, embodiments of the present disclosure will not be limited thereto.

Referring to FIG. 8, the plurality of sub-pixels PX may be arranged in an array in the first direction X and the second direction Y. However, embodiments of the present disclosure will not be limited thereto. For convenience of description, in embodiments of the present disclosure, the plurality of sub-pixels PX arranged in the first direction X are referred to as a row of sub-pixels PX, and the plurality of sub-pixels PX arranged in the second direction Y are referred to as a column of sub-pixels PX.

The display panel 210 further includes a plurality of gate lines GL and a plurality of data lines DL located in at least the display region AA on the base substrate 200. The plurality of data lines DL extend in the second direction Y, and the plurality of gate lines GL extend in the first direction X. For example, a sub-pixel PX is connected to a data line DL and a gate line GL, sub-pixels PX in the same row are connected to the same gate line GL, sub-pixels PX in different rows are connected to different gate lines GL; sub-pixels PX in the same column are connected to the same data line DL, and sub-pixels PX in different columns are connected to different data lines DL.

The peripheral region NA may be disposed on at least one side of the display region AA. For example, the peripheral region NA may surround an outer periphery of the display region AA. In embodiments of the present disclosure, the peripheral region NA may include a vertical portion extending in the first direction X and a horizontal portion extending in the second direction Y.

The display panel 210 may further include a gate driving circuit 21 and a display binding pad PAD1 located in the peripheral region NA on the base substrate 200. In the peripheral region NA, the gate driving circuit 21 may be located on at least one side of the display region AA. In the embodiment shown in FIG. 8, the gate driving circuits 21 are located on left and right sides of the display region AA, respectively. It should be noted that the left and right sides may refer to left and right sides of the display panel 210 when viewed by the human eyes in the “horizontal display” mode. The display binding pad PAD1 may be located on at least one side of the display region AA. In the embodiment shown in FIG. 8, the display binding pad PAD1 is located on an upper side of the display region AA. It should be noted that the upper side may refer to an upper side of the display panel 210 when viewed by the human eyes in the “horizontal display” mode.

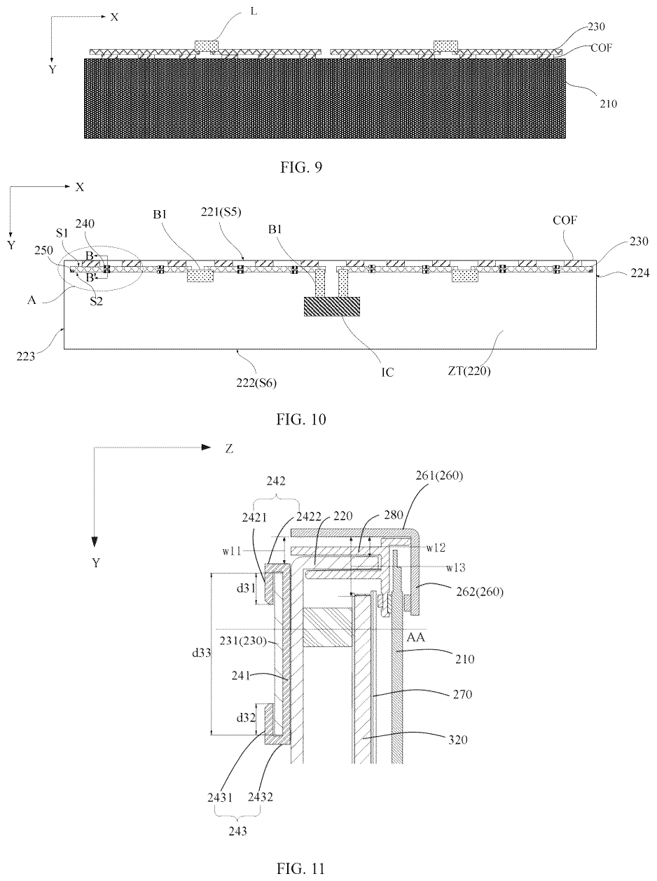

FIG. 9 schematically shows a schematic diagram of a connection between a first circuit board and a display panel according to embodiments of the present disclosure, and FIG. 10 schematically shows a schematic diagram of a connection between a first circuit board and a backboard according to embodiments of the present disclosure. It should be noted that, for clarity of presentation, the first circuit board is made transparent in FIG. 10.

Referring to FIG. 8 to FIG. 10, the display binding pad PAD1 is used to be electrically connected to a display driver chip IC. For example, the display binding pad PAD1 may be electrically connected to the display driver chip IC through the COF and a first circuit board 230. The display driver chip IC includes a data driving circuit, and the data driving circuit is used to sequentially latch input data according to a clock signal, convert the latched data into an analog signal, and input the analog signal to each data line DL of the display panel 210. The gate driving circuit 21 is usually implemented by a shift register, and the shift register converts the clock signal into an on/off voltage and outputs it to each gate line GL of the display panel 210, respectively.

It should be noted that, although FIG. 8 shows that the gate driving circuit 21 is located on the left and right sides of the display region AA and the display binding pad PAD1 is located on the upper side of the display region AA, embodiments of the present disclosure will not be limited thereto, and the gate driving circuit 21 and the display binding pad PAD1 may be located at any appropriate positions in the peripheral region NA.

For example, the gate driving circuit 21 may adopt a GOA (i.e., Gate Driver on Array) technology. In the GOA technology, the gate driving circuit 21 is directly disposed on an array substrate instead of using an external chip. Each GOA unit serves as a stage of shift register, and each stage of shift register is connected to a gate line GL. By sequentially outputting scanning signals by each stage of shift register, progressive scanning of the sub-pixels PX may be realized. In some embodiments, each stage of shift register may also be connected to a plurality of gate lines GL. This may adapt to a development trend of a high resolution and a narrow bezel of the display panel 210.

Referring to FIG. 7, the display module 200 further includes a backboard 220 disposed on a back side of the display panel 210. In embodiments of the present disclosure, the display panel 210 may be a liquid crystal display panel 210 having a light-emitting side and a light-incident side. The back side of the display panel 210 may refer to the light-incident side of the display panel 210, and the light-emitting side of the display panel 210 is used to display a picture. Therefore, the light-emitting side of the display panel 210 may also be referred to as a display side.

In embodiments of the present disclosure, the display panel 210 includes a liquid crystal layer, and a pixel electrode and a common electrode disposed on at least one side of the liquid crystal layer. The pixel electrode and the common electrode may apply a first electric field in response to a driving signal, and liquid crystals in the liquid crystal layer may deflect under an action of the first electric field, thereby realizing a display function.

Referring to FIG. 10, the display module 200 further includes a first circuit board 230 disposed on a side of the backboard 220 away from the display panel 210. The first circuit board 230 extends in the first direction X, the first circuit board 230 includes a first side S1 and a second side S2 oppositely disposed in the second direction Y, the first side S1 is electrically connected to the display binding pad, and the second side S2 is used to be electrically connected to the display driver chip IC.

In embodiments of the present disclosure, a shape of the first circuit board 230 may include a strip shape, and the first side S1 and the second side S2 of the first circuit board 230 may refer to two long sides of the first circuit board 230 oppositely disposed in the second direction Y. For example, the first side S1 of the first circuit board 230 may be an upper side of the first circuit board 230 in FIG. 10, and the second side S2 of the first circuit board 230 may be a lower side of the first circuit board 230 in FIG. 10. The first side S1 of the first circuit board 230 may be electrically connected to the display binding pad PAD through the COF. For example, the first side S1 of the first circuit board 230 may be electrically connected to the display binding pad PAD through the COF.

The display module 200 further includes a flexible clasper assembly 240 disposed on a side of the backboard 220 away from the display panel 210.

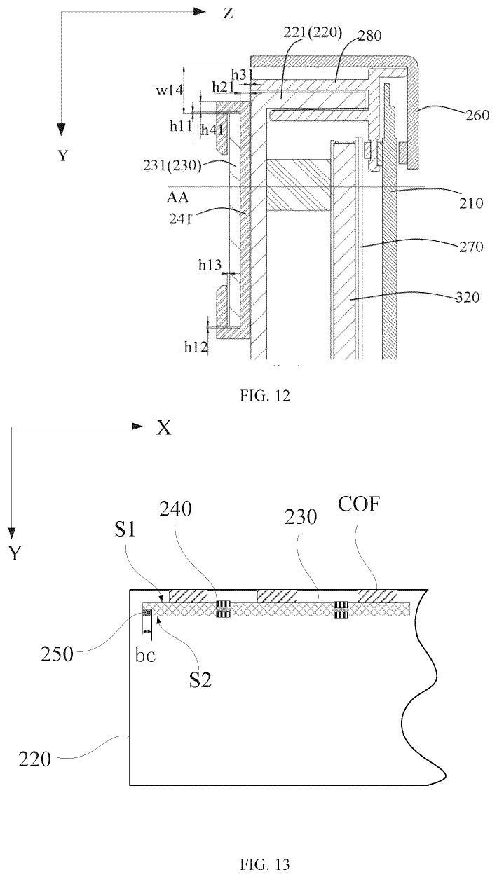

FIG. 11 and FIG. 12 schematically show cross-sectional views taken along section line BB′ in FIG. 10.

Referring to FIG. 11 and FIG. 12, a flexible clasper assembly 240 includes: a substrate 241, a first flexible clasper 242, and a second flexible clasper 243. The substrate 241 is fixedly connected to the backboard 220, the first flexible clasper 242 and the second flexible clasper 243 are disposed on a side of the substrate 241 away from the display panel 210, the first flexible clasper 242 and the second flexible clasper 243 are oppositely disposed in the second direction Y, and the first flexible clasper 242 and the second flexible clasper 243 are used to clamp the first circuit board 230 and allow a displacement of the first circuit board 230 within a first preset range in the second direction Y.

In embodiments of the present disclosure, the substrate 241 may be fixed to the backboard 220 by means of bonding, screws, or other methods. The specific method may be determined according to actual needs, which will not be limited here. Referring to FIG. 11, the display panel 210 is disposed on a right side of the backboard 220, and the first flexible clasper 242 and the second flexible clasper 243 are disposed on a left side of the backboard 220. The first flexible clasper 242 and the second flexible clasper 243 are oppositely disposed, and they respectively press a left surface of the first circuit board 230, so as to clamp the first circuit board 230. The first flexible clasper 242 and the second flexible clasper 243 have flexibility, so that they may deform to a certain extent in the second direction Y. Furthermore, the deformed first flexible clasper 242 and second flexible clasper 243 may enable the first circuit board 230 to displace slightly in the second direction Y, that is, allow the displacement of the first circuit board 230 within a first preset range in the second direction Y. A size of the first preset range is positively correlated with deformability of the first flexible clasper 242 and the second flexible clasper 243. Therefore, the size of the first preset range may be controlled by materials of the first flexible clasper 242 and the second flexible clasper 243. For example, the first flexible clasper 242 and the second flexible clasper 243 may be made of rubber, and a rubber material has appropriate hardness. This may not only ensure a degree of freedom of displacement of the first circuit board 230 in the second direction Y, but also prevent disengagement of the first flexible circuit board due to excessive deformation of the first flexible clasper 242 (or the second flexible clasper 243).

FIG. 13 schematically shows a schematic diagram of position A in FIG. 10.

Referring to FIG. 13, the display module 200 further includes conductive foam 250 disposed on a side of the backboard 220 away from the display panel 210. At least one corner of the first circuit board 230 is bonded to the backboard 220 through the conductive foam 250, and the conductive foam 250 allows a displacement of the first circuit board 230 within a second preset range in the first direction X.

In embodiments of the present disclosure, the conductive foam 250 is sandwiched between the backboard 220 and the first circuit board 230. Both a side of the conductive foam 250 facing the backboard 220 and a side of the conductive foam 250 facing the first circuit board 230 are provided with an adhesive, so that the conductive foam 250 may bond the backboard 220 and the first circuit board 230 together. A corner of the first circuit board 230 may be provided with an exposed metal region. The conductive foam 250 has electrical conductivity. The conductive foam 250 may press against the exposed metal region, so that components, wiring, etc. on the exposed metal region are electrically connected to a grounding structure on the backboard 220, thereby preventing electrostatic breakdown of the first circuit board 230.

The conductive foam 250 may deform to a certain extent in the first direction X. The deformed conductive foam 250 enables the first circuit board 230 to displace slightly in the first direction X, that is, allow the displacement of the first circuit board 230 within a second preset range in the first direction X. A size of the second preset range is positively correlated with deformability of the conductive foam 250. The size of the second preset range may be controlled by a compression ratio of the conductive foam 250. The compression ratio of the conductive foam 250 may be set in a range of 40% and 60%. For example, the compression ratio of the conductive foam may be set to 50%. This may not only ensure a degree of freedom of displacement of the first circuit board 230 in the first direction X, but also prevent a failure of bonding or grounding function due to excessive deformation of the conductive foam 250.

Therefore, through embodiments of the present disclosure, the first circuit board 230 may have a certain degree of freedom of displacement in both the first direction X and the second direction Y. In this way, no matter whether in the “horizontal display” mode or the “vertical display” mode, when the display panel 210 sinks, the first circuit board 230 may also move accordingly under an action of gravity (or under an action of a pulling force of the COF), thereby alleviating pulling on the COF. At the same time, through the cooperation of the flexible clasper assembly 240 and the conductive foam 250, the first circuit board 230 may be allowed to displace to a greater extent in the first direction X (compared to a displacement in the second direction Y). In the “vertical display” mode, when the display panel 210 sinks, the first circuit board 230 sinks synchronously under an action of gravity (or additionally the pulling force of the COF), thereby reducing or even eliminating pulling on the COF. Therefore, the black-state light leakage problem caused thereby may be improved, which is beneficial to expanding application scenarios of the display module 200 (large-sized strip-shaped display module 200) to the “vertical display” mode and realizing a better display effect.

The display module 200 according to embodiments of the present disclosure will be further described below with reference to FIG. 5 to FIG. 30.

It should be noted that, for clarity of description, unless otherwise specified, a size design of each component in embodiments of the present disclosure will be described by taking an 86-inch strip-shaped display module 200 (with a long-side length of 2.2 m and a short-side length of 0.36 m) as an example.

Referring to FIG. 11 and FIG. 12, in some specific embodiments, a portion of the first circuit board 230 clamped by the first flexible clasper 242 and the second flexible clasper 243 includes a first fixed portion 231. In a thickness direction of the display module 200, the first flexible clasper 242 overlaps the first fixed portion 231, and an overlapping region (hereinafter also referred to as a first overlapping region) has a first dimension d31 in the second direction Y. In a thickness direction Z of the display module 200, the second flexible clasper 243 overlaps the first fixed portion 231, and an overlapping region (hereinafter also referred to as a second overlapping region) has a second dimension d32 in the second direction Y. The first fixed portion 231 has a third dimension d33 in the second direction Y.

The first circuit board 230 is a strip-shaped structure extending in the first direction X, and the first circuit board 230 includes two short sides oppositely disposed in the first direction X and two long sides arranged in the second direction Y. The first flexible clasper 242 and the second flexible clasper 243 are clamped on the two long sides of the first circuit board 230. The portion of the first circuit board 230 clamped by the first flexible clasper 242 and the second flexible clasper 243 may refer to a portion of the first circuit board 230 between the first flexible clasper 242 and the second flexible clasper 243, i.e., the first fixed portion 231.

Referring to FIG. 11, a left end of the first flexible clasper 242 extends downward and presses against a left surface of an upper end of the first fixed portion 231, thereby forming the first overlapping region. A left end of the second flexible clasper 243 extends upward and presses against a left surface of a lower end of the first fixed portion 231, thereby forming the second overlapping region. The first dimension d31 may refer to an average length of the first overlapping region in a vertical direction in FIG. 11, the second dimension d32 may refer to an average length of the second overlapping region in the vertical direction in FIG. 11, and the third dimension d33 may refer to an average length of the first fixed portion 231 in the vertical direction in FIG. 11.

Since the first flexible clasper 242 and the second flexible clasper 243 are softer than a conventional rigid clasper, embodiments of the present disclosure may enable the first flexible clasper 242 and the second flexible clasper 243 to press against the first circuit board 230 to a greater extent. For example, a ratio of a sum of the first dimension d31 and the second dimension d32 to the third dimension d33 is greater than or equal to ⅓ and less than or equal to ½. In other words, the sum of the first dimension d31 and the second dimension d32 is greater than ⅓ of the third dimension d33 and less than ½ of the third dimension d33. The first dimension d31 may be the same as the second dimension d32. For example, the first dimension d31 may be set in a range of 3.5 mm to 4.5 mm, such as 3.85 mm. For example, the second dimension d32 may be set in a range of 3.5 mm to 4.5 mm, such as 3.85 mm. The third dimension d33 may be set in a range of 15 mm to 25 mm, such as 20 mm. This may prevent disengagement of the first circuit board 230 from the first flexible clasper 242 and the second flexible clasper 243 while ensuring assembly convenience.

In some specific embodiments, the first flexible clasper 242 includes a first pressing portion 2421 and a first connecting portion 2422, where the first pressing portion 2421 is connected to the substrate 241 through the first connecting portion 2422. The second flexible clasper 243 includes a second pressing portion 2431 and a second connecting portion 2432, where the second pressing portion 2431 is connected to the substrate 241 through the second connecting portion 2432. In the thickness direction Z of the display module 200, the first pressing portion 2421 and the second pressing portion 2431 overlap the first fixed portion 231.

Referring to FIG. 11 and FIG. 12, the first pressing portion 2421 may refer to a portion of the first flexible clasper 242 that extends downward from its left end, and the second pressing portion 2431 may refer to a portion of the second flexible clasper 243 that extends upward from its left end. Accordingly, the first connecting portion 2422 may refer to a portion connected between the first pressing portion 2421 and the substrate, and the second connecting portion 2432 may refer to a portion connected between the second pressing portion 2431 and the substrate.

In the second direction Y, a first gap h11 is provided between the first fixed portion 231 and the first connecting portion 2422, and a second gap h12 is provided between the first fixed portion 231 and the second connecting portion 2432. In the thickness direction Z of the display module 200, a third gap h13 is provided between either the first pressing portion 2421 or the second pressing portion 2431 and the first fixed portion 231. Either the first gap h11 or the second gap h12 is less than the third gap h13.

Through the first gap h11 and the second gap h12, the first circuit board 230 may have a greater degree of freedom of displacement in the second direction Y. At the same time, since both the first gap h11 and the second gap h12 are less than the third gap h13, the first gap h11 and the second gap h12 may not be excessively large, thereby preventing offset of the first circuit board 230.

For example, the first gap h11 may be set in a range of 0.1 mm to 0.2 mm, such as 0.15 mm. The second gap h12 may be set in a range of 0.1 mm to 0.2 mm, such as 0.15 mm. The third gap h13 may be set in a range of 0.15 mm to 0.25 mm, such as 0.2 mm. This may prevent a fixing failure due to an excessively large gap on the basis of enabling the first circuit board 230 to have a greater degree of freedom of displacement in the second direction Y.

In some specific embodiments, the display module 200 further includes a front frame 260 and an optical film 270. The optical film 270 is located on a side of the backboard 220 close to the display panel 210. The front frame 260 includes a first frame body 261 extending in the thickness direction Z of the display module 200. In the second direction Y, the first frame body 261 is located on a side of the backboard 220 away from a center of the display module. In the second direction Y, a first distance w11 is provided between the flexible clasper assembly 240 and the first frame body 261, a second distance w12 is provided between the backboard 220 and the first frame body 261, and a third distance w13 is provided between the optical film 270 and the first frame body 261. The first distance w11 is greater than the second distance w12 and less than the third distance w13.

The first frame body 261 extends in a horizontal direction in FIG. 11, and the first frame body 261 may be an annular structure surrounding an outer periphery of the backboard 220. The front frame 260 may further include a third frame body 262, and the third frame body 262 and the first frame body 261 are formed as an integrated structure. The third frame body 262 may extend horizontally toward the center of the display module 200 and overlap the display panel 210 in the thickness direction Z of the display module 200.

Referring to FIG. 11, the first distance w11 may refer to an average distance between an upper side of the flexible clasper assembly 240 and a lower side of the first frame body 261, the second distance w12 may refer to an average distance between an upper side of the backboard 220 and the lower side of the first frame body 261, and the third distance w13 may refer to an average distance between an upper side of the optical film 270 and the lower side of the first frame body 261.

For example, the first distance w11 may be set in a range of 2.5 mm to 3.5 mm, such as 2.9 mm.

In some specific embodiments, a thickness h21 of the substrate 241 may be set to 1.5 mm, and the thickness h21 of the substrate 241 may include a thickness h31 of an adhesive attached between the substrate 241 and the backboard 220. In the second direction Y, a distance w14 between the first circuit board 230 and the first frame body 261 may be set in a range of 4 mm to 5 mm, such as 4.4 mm. Optionally, a material compression ratio of the flexible clasper assembly 240 may be set to 50%, which may not only effectively fix the first circuit board 230, but also ensure a small degree of freedom of displacement of the first circuit board 230 in the second direction Y. The thickness of the substrate 241 may be adjusted according to a requirement for a bezel width. If the module requires a narrow bezel, the thickness of the substrate 241 may be appropriately increased, and if the module has a low requirement for the bezel width, the thickness of the substrate 241 may be designed to be thinner. However, a minimum thickness of the substrate 241 is greater than or equal to 0.8 mm, so as to avoid a risk of failure of a clamping function.

Optionally, a thickness h41 of the first connecting portion 2422 and the second connecting portion 2432 may be the same as the thickness h21 of the substrate 241, which may ensure a sufficient bending space of the COF under a low-temperature condition (e.g., −20° C.).

Referring to FIG. 10, in some specific embodiments, the first circuit board 230 is electrically connected to the display binding pad PAD through a plurality of COFs arranged in the first direction X. The display module 200 includes a plurality of flexible clasper assemblies 240 arranged in the first direction X, and at least one flexible clasper assembly 240 is provided between at least two adjacent COFs.

The display module 200 includes a plurality of first circuit boards 230 arranged in the first direction X. Each first circuit board 230 is electrically connected to the display binding pad PAD through a plurality of COFs. For example, the plurality of COFs are arranged in a horizontal direction in FIG. 10. On a same first circuit board 230, at least one flexible clasper assembly 240 is provided between every two adjacent COFs, so that the flexible clasper assemblies 240 may be evenly distributed in the first direction X.

For example, a distance between two adjacent flexible clasper assemblies 240 may be set in a range of 250 mm to 350 mm, such as 295 mm. A dimension of the flexible clasper assembly 240 in the first direction X may be set in a range of 8 mm to 12 mm, such as 10 mm. In this way, an appropriate distance may be maintained between the flexible clasper assemblies 240, and the flexible clasper assemblies 240 may be evenly distributed on the backboard 220 while ensuring an effectiveness of fixation. At the same time, the dimension of the flexible clasper assembly 240 in the first direction X is designed, so that the flexible clasper assembly 240 may have a sufficient size pressing against the first circuit board 230 while minimizing a space occupied by the flexible clasper assembly 240 in the first direction X.

Referring to FIG. 10 and FIG. 12, in some specific embodiments, the backboard 220 includes a backboard main body ZT, and a first bending portion 221 and a second bending portion 222 disposed on the backboard main body ZT. The first bending portion 221 and the second bending portion 222 are bent toward the display panel 210 and are oppositely disposed in the second direction Y. In the second direction Y, the first circuit board 230 is located between the first bending portion 221 and the second bending portion 222, and a distance between the first bending portion 221 and the first circuit board 230 is less than a distance between the second bending portion 222 and the first circuit board 230. In the thickness direction Z of the display module 200, the first flexible clasper 242 overlaps the first bending portion 221.

Referring to FIG. 10, the first bending portion 221 and the second bending portion 222 may refer to bending portions located on two long sides of the backboard 220. The first bending portion 221 may be a bending portion on an upper side, and the second bending portion 222 may be a bending portion on a lower side. The first bending portion 221 is closer to the first circuit board 230 than the second bending portion 222.

Referring to FIG. 12, the first bending portion 221 is bent toward a right side. An upper side of the first flexible clasper 242 is located between a lower side of the first bending portion 221 and an upper side of the first bending portion 221, so that the first bending portion 221 may be positioned as high as possible, and at the same time, the first bending portion 221 may not be positioned too high to cause the first flexible clasper 242 to be suspended, thus affecting a fixing effect.

Referring to FIG. 13, in some specific embodiments, the second side S2 of the first circuit board 230 includes a first corner and a second corner oppositely disposed in the first direction X. At least one of the first corner or the second corner includes an exposed metal region, and the conductive foam 250 at least partially covers the exposed metal region.

Referring to FIG. 13, the first corner and the second corner may refer to a lower-left corner and a lower-right corner of the first circuit board 230, and one of the two corners is provided with an exposed metal region. For example, the display module 200 includes a plurality of first circuit boards 230 arranged in the first direction X, and two adjacent first circuit boards 230 are electrically connected to the display driver chip IC through a same second circuit board B1. For any one of the first circuit boards 230, the first corner may refer to one of the first corner and the second corner that is closer to the second circuit board B1, and the second corner may refer to one of the first corner and the second corner that is away from the second circuit board B1. The second corner is provided with an exposed metal region.

In embodiments of the present disclosure, the conductive foam 250 has electrical conductivity. One end of the conductive foam 250 is electrically connected to the exposed metal region, and the other end of the conductive foam 250 is electrically connected to the grounding structure on the backboard 220, thereby realizing grounding of the exposed metal region and further preventing electrostatic breakdown of the first circuit board 230. That is to say, in embodiments of the present disclosure, the conductive foam 250 may not only enable the first circuit board 230 to have a certain degree of freedom of displacement in the first direction X, but also meet a grounding requirement for the first circuit board 230.

In some specific embodiments, a dimension of the conductive foam 250 in the first direction X is set in a range of 4 mm to 6 mm, a dimension of the conductive foam 250 in the second direction Y is set in a range of 4 mm to 6 mm, and a thickness of the conductive foam 250 is set in a range of 1 mm to 3 mm. In this way, on the basis of enabling the first circuit board 230 to have a certain degree of freedom of displacement in the first direction X, effective fixing of the first circuit board 230 may be ensured. At the same time, the conductive foam 250 may effectively cover the exposed metal region, so as to meet the grounding requirement.

For example, the conductive foam 250 may be square, which will not constitute a limitation to embodiments of the present disclosure. The conductive foam 250 may be of any suitable shape. For example, a side length be of the conductive foam 250 is 5 mm, and a thickness of the conductive foam 250 is 2 mm. The conductive foam 250 may be slightly less than the exposed metal region, for example, by 1 mm to 2 mm.

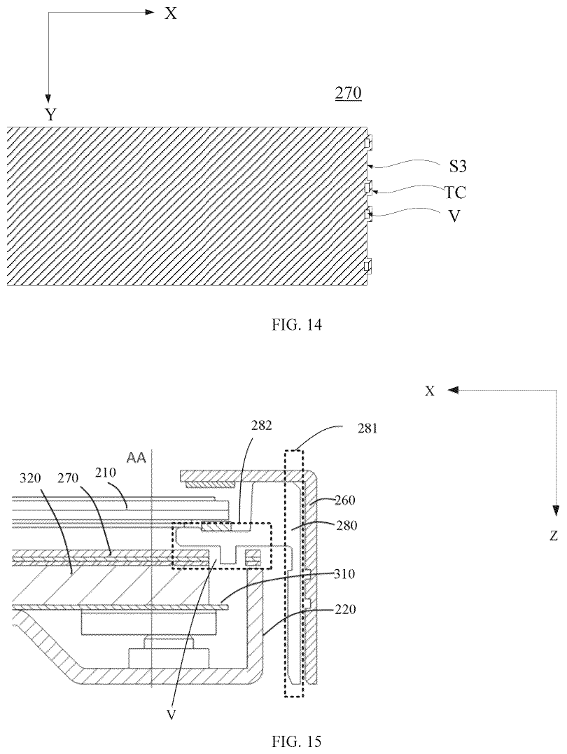

FIG. 14 schematically shows a plan view of an optical film in embodiments of the present disclosure, and FIG. 15 schematically shows a cross-sectional view taken along section line CC′ in FIG. 5.

Referring to FIG. 14 and FIG. 15, in some specific embodiments, the display module 200 further includes an optical film 270 and a plastic frame 280. The optical film 270 is disposed between the backboard 220 and the display panel 210. The optical film 270 includes a third side S3 and a fourth side S4 oppositely disposed in the first direction X, and a lug hole V is provided on the third side S3. The plastic frame 280 includes a second frame body 281 extending in the thickness direction Z of the display module 200, and the second frame body 281 is located on a side of the third side S3 of the optical film 270 away from a center of the optical film 270. The plastic frame 280 further includes a lug structure 282 disposed on the second frame body 281, and the lug structure 282 extends toward the optical film 270. In the thickness direction Z of the display module 200, the lug structure 282 overlaps the lug hole V, and in the overlapping region, the lug structure 282 passes through the lug hole V.

The optical film 270 may include a composite prism 271, a diffuser 272, etc. The third side S3 and the fourth side S4 of the optical film 270 may refer to two short sides of the optical film 270 that are oppositely disposed. When the display module 200 is in the “vertical display” mode, the fourth side S4 of the optical film 270 is a side close to the ground, and the third side S3 of the optical film 270 is a side away from the ground.

For example, the second frame body 281 extends in a vertical direction in FIG. 15, and the lug structure 282 extends in a horizontal direction in FIG. 15. A portion of the lug structure 282 located above the lug hole V is provided with a lug rib extending downward, and the lug rib passes through the lug hole V to form a limit to the lug hole V. Compared with a conventional solution that the lug rib being disposed on the backboard 220, the arrangement of the lug rib on the plastic frame 280 may save a corresponding structure on the backboard 220, which is beneficial to realize a narrow bezel.

In embodiments of the present disclosure, the lug hole V is provided on the third side S3 of the optical film 270, and the lug structure 282 is correspondingly provided on the second frame body 281. In this way, when the display module 200 is in the “vertical display” mode, the optical film 270 may be limited by matching of the lug hole V and the lug structure 282, thereby preventing the optical film 270 from sinking.

In embodiments of the present disclosure, the display module 200 may be applied in a wide-temperature environment. Upper and lower temperature limits of the wide-temperature environment exceed a conventional temperature range, and even exceed a critical temperature at which at least part of a film material of the display module 200 is deformed. For example, the conventional temperature range is −5° C. to 60° C., and a temperature range of the wide-temperature environment may reach −20° C. to 80° C. In the wide-temperature environment, the plastic frame 280 may be deformed. In the “vertical display” mode, the deformed plastic frame 280 is difficult to form an effective support for the optical film 270. For example, when the temperature reaches 80° C., the lug structure 282 on the plastic frame 280 may sink. At this case, the lug hole V may sink synchronously and deviate from a predetermined position, which may lead to an obvious light leakage problem.

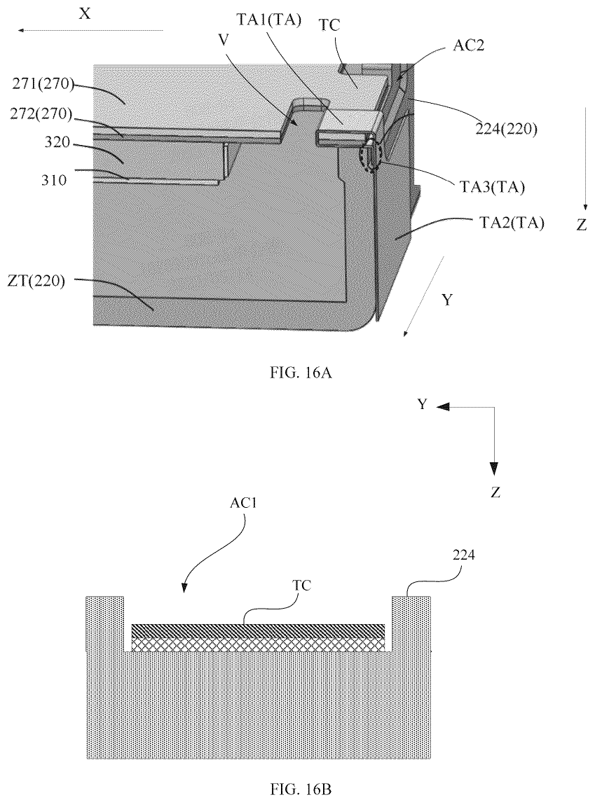

FIG. 16A schematically shows a schematic diagram of an auxiliary fixing tape in embodiments of the present disclosure.

Referring to FIG. 10 and FIG. 16A, in some specific embodiments, a lug protrusion TC is further fixedly provided on the third side S3 of the optical film 270, and the lug protrusion TC is located on a side of the lug hole away from the center of the optical film. The display module 200 further includes an auxiliary fixing tape TA. The backboard 220 includes a backboard main body ZT, and a third bending portion 223 and a fourth bending portion 224 disposed on the backboard main body ZT. The third bending portion 223 and the fourth bending portion 224 are bent toward the display panel 210 and are oppositely disposed in the first direction X. A side of the third bending portion 223 away from the center of the display module 200 is flush with the fourth side S4 of the optical film 270. The auxiliary fixing tape TA includes a winding portion TA1 and a first bonding portion TA2. The winding portion TA1 passes through the lug hole V and is wound around the lug protrusion TC, and the first bonding portion TA2 is bonded to the fourth bending portion 224.

In embodiments of the present disclosure, the third bending portion 223 and the fourth bending portion 224 may refer to bending portions located on two short sides of the backboard 220 that are oppositely disposed. For example, the third bending portion 223 is located at a left end of the backboard 220 in FIG. 10, and the fourth bending portion 224 is located at a right end of the backboard 220 in FIG. 10.

In embodiments of the present disclosure, “a side of the third bending portion 223 away from the center of the display module 200 is flush with the fourth side S4 of the optical film 270” and similar expressions may mean that surfaces on a side of the two away from the center of the display module 200 are substantially located in the same horizontal plane.

The winding portion TA1 may have a strip shape. For example, the winding portion TA1 is wound around the lug protrusion TC located on a right side of the lug hole V in FIG. 16A. The first bonding portion TA2 is bonded to the fourth bending portion 224. The backboard 220 may include a metal material, which is much less affected by temperature than the plastic frame 280. Even when the temperature reaches 80° C., a shape of the fourth bending portion 224 may still remain stable. In this case, even if the plastic frame 280 is deformed to cause the lug structure 282 to sink, the auxiliary fixing tape TA may tightly fasten the lug hole V, thereby fixing the optical film 270 at a predetermined position and preventing a light leakage problem caused by deviation of the lug hole V.

FIG. 16B schematically shows a schematic diagram of a first groove in embodiments of the present disclosure. For clarity of presentation, FIG. 16B only shows a partial region on the fourth bending portion 224 that is close to the first groove AC1.

Referring to FIG. 16A and FIG. 16B, in some specific embodiments, a first groove AC1 is provided on a side of the fourth bending portion 224 close to the display panel, the first groove AC1 is recessed toward the backboard main body ZT, and the lug protrusion TC is lapped in the first groove AC1. For example, the first groove AC1 is recessed downward in FIG. 16B, thereby providing a space for the lug protrusion TC, restricting a displacement of the lug protrusion TC, and further ensuring stability of the optical film 270.

In some specific embodiments, the second frame body 281 is located on a side of the fourth bending portion 224 away from the center of the display module. The first bonding portion TA2 is bonded to a surface of the fourth bending portion 224 facing the second frame body 281, and a gap is provided between the first bonding portion TA2 and the second frame body 281.

The first bonding portion TA2 may be bonded to a surface of the fourth bending portion 224 facing the second frame body 281. The surface is adjacent to the lug hole V and has a large area, so that a bonding area between the first bonding portion TA2 and the fourth bending portion 224 is as large as possible, which is beneficial to enhancing a bonding stability between the auxiliary fixing tape TA and the backboard 220.

For example, the gap between the first bonding portion TA2 and the second frame body 281 is set in a range of 0.15 mm to 0.25 mm, such as 0.2 mm. For example, an overall thickness of the auxiliary fixing tape TA is set in a range of 0.05 mm to 0.18 mm, such as a range of 0.1 mm to 0.15 mm. Optionally, adhesiveness (a tape peeling force) of the auxiliary fixing tape TA is greater than or equal to 1500 kgf/25 mm. This may not only ensure stability of the auxiliary fixing tape TA, but also prevent the second frame body 281 and the fourth bending portion 224 from being squeezed by the auxiliary fixing tape TA.

In some specific embodiments, the auxiliary fixing tape TA further includes an intermediate portion TA3 between the winding portion TA1 and the first bonding portion TA2. An end of the winding portion TA1 is bonded to the intermediate portion TA3 after bypassing an edge of the lug hole V. The fourth bending portion 224 includes a second groove AC2 recessed toward a side away from the second frame body 281, and the end of the winding portion TA1 is at least partially located in the second groove AC2. For example, referring to FIG. 16A, a bonding portion between the end of the winding portion TA1 and the intermediate portion TA3 is located in the second groove AC2, more space may be provided through the second groove AC2. The end of the winding portion TA1 overlap the intermediate portion TA3 in the first direction X, and in an overlapping region, a surface of the end of the winding portion TA1 facing the intermediate portion and a surface of the intermediate portion TA3 facing the end of the winding portion TA1 are bonded to each other. A portion of the above-mentioned overlapping region where the end of the winding portion TA1 and the intermediate portion TA3 are located is the bonding portion of the two.

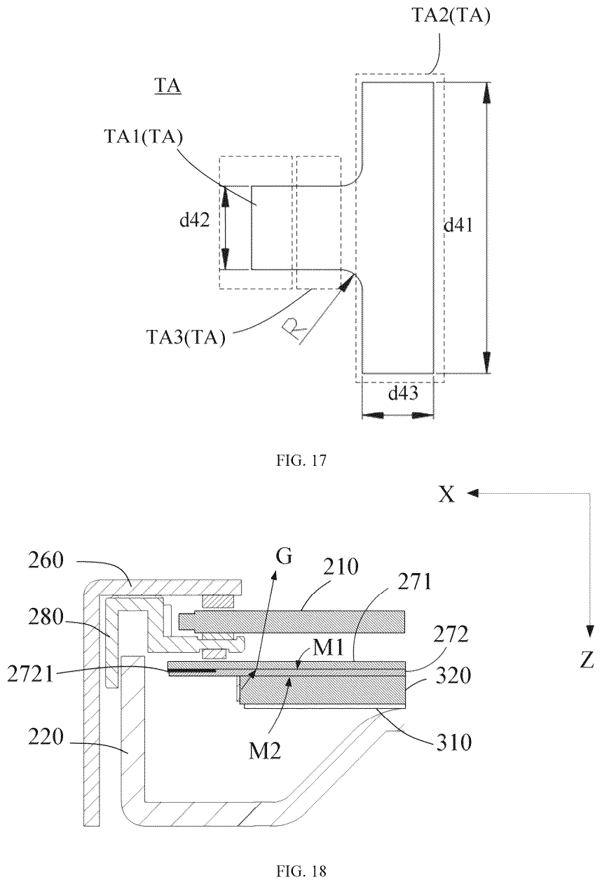

FIG. 17 schematically shows a schematic diagram of an auxiliary fixing tape after being unfolded in embodiments of the present disclosure.

Referring to FIG. 17, in some specific embodiments, a dimension d41 of the first bonding portion TA2 in the second direction Y is greater than a dimension d42 of the intermediate portion TA3 in the second direction Y. A transition corner R is provided at a junction of the first bonding portion TA2 and the intermediate portion TA3, and the transition corner R includes an arc-shaped corner.

For example, the auxiliary fixing tape TA may be T-shaped after being unfolded. The dimension d42 of the intermediate portion TA3 in the second direction Y is greater than or equal to 8 mm. A length of the winding portion TA1 needs to be sufficient to realize effective bonding with the intermediate portion TA3 after winding around a film lug once, and a bonding width needs to be greater than or equal to 1 mm, so as to ensure effective fixing of the auxiliary fixing tape TA to the optical film 270. A radius of the arc-shaped corner is greater than or equal to 0.5 mm, so as to avoid a strength failure caused by tearing at the corner. Optionally, the dimension d41 of the first bonding portion TA2 in the second direction Y is greater than or equal to 25 mm, and a dimension d43 of the first bonding portion TA2 in the thickness direction Z of the display module is greater than or equal to 6 mm.

In some specific embodiments, the first bonding portion TA2 is bonded to two adjacent side surfaces of the fourth bending portion 224. For example, the first bonding portion TA2 is bonded to both a surface of the fourth bending portion 224 facing the second frame body 281 and a surface of the fourth bending portion 224 away from the display panel 210. This may not only increase a bonding area, but also disperse forces, thereby improving bonding stability.

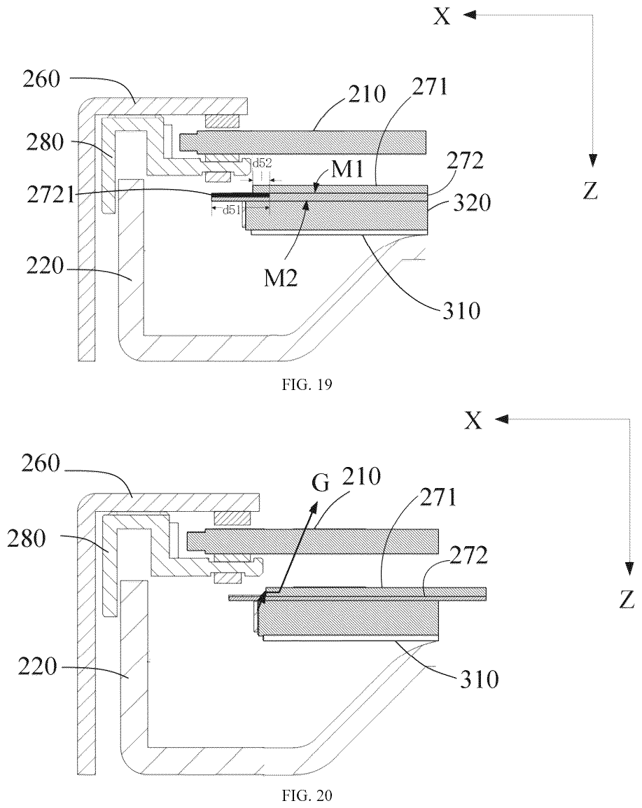

FIG. 18 and FIG. 19 schematically show schematic diagrams of a first light-shielding structure in embodiments of the present disclosure, and FIG. 20 schematically shows a schematic diagram of light leakage caused by shrinkage of a composite prism and a diffuser.

Referring to FIG. 10 and FIG. 18 to FIG. 20, in some specific embodiments, the optical film 270 includes the composite prism 271 and the diffuser 272. In the first direction X, the diffuser 272 includes a first surface M1 and a second surface M2 oppositely disposed in a thickness direction of the diffuser 272. The first surface M1 is located on a side of the second surface M2 close to the composite prism 271, and a first light-shielding structure 2721 is provided on the first surface M1. The first surface M1 includes a lug side and an opposite lug side oppositely disposed in the first direction X. The lug hole is located on the lug side, and the first light-shielding structure 2721 is located on the opposite lug side.

For example, the first surface of the diffuser 272 may refer to an upper surface of the diffuser 272 in FIG. 19, and the second surface of the diffuser 272 may refer to a lower surface of the diffuser 272 in FIG. 19. The lug side is a side of the diffuser 272 provided with the lug hole V as described in the previous embodiments. The opposite lug side is a side of the diffuser 272 that is opposite to the lug side. For example, the opposite lug side may refer to a left side of the diffuser 272 in FIG. 19.

In embodiments of the present disclosure, the display module may operate at 80° C. At 80° C., both the composite prism 271 and the diffuser 272 shrink, but a shrinkage degree of the composite prism 271 is greater than a shrinkage degree of the diffuser 272. Referring to FIG. 20, the shrinkage degree of the composite prism 271 is much greater than the shrinkage degree of the diffuser 272, so that a portion of the diffuser 272 may be exposed. The exposed portion may cause light G emitted from the light source assembly to be incident onto a side surface of the composite prism 271 via the diffuser 272, thereby leading to light leakage. As shown in FIG. 19, in embodiments of the present disclosure, the first light-shielding structure 2721 may play a light-shielding role, thereby alleviating a light leakage problem to a certain extent.

In some specific embodiments, a dimension of the first light-shielding structure in the first direction is set in a range of 2 mm to 4 mm. For example, a dimension d51 of the first light-shielding structure 2721 in the first direction X is 3 mm. In this way, at 80° C., the first light-shielding structure 2721 may cover the portion of the diffuser 272 exposed by the composite prism 271. In this way, even if the composite prism 271 shrinks to exposes a portion of the diffuser 272, since the exposed portion is shielded by the first light-shielding structure 2721, light may not be incident onto the side surface of the composite prism 271.

In some specific embodiments, after the composite prism 271 shrinks, the first light-shielding structure 2721 may also cover an edge of the composite prism. For example, after the composite prism 271 shrinks, the first light-shielding structure 2721 may cover the edge of the composite prism 271 by a certain dimension d52, for example, d52≥1 mm, which may prevent a partially overlapping portion between the first light-shielding structure 2721 and the edge of the composite prism 271 from not overlapping due to a process fluctuation.

In other specific embodiments, the optical film 270 includes a single prism and the diffuser 272. The lug hole V penetrates the single prism and the diffuser 272, and a thermal shrinkage rate of the single prism is the same as a thermal shrinkage rate of the diffuser 272. In this case, the first light-shielding structure 2721 may be omitted.

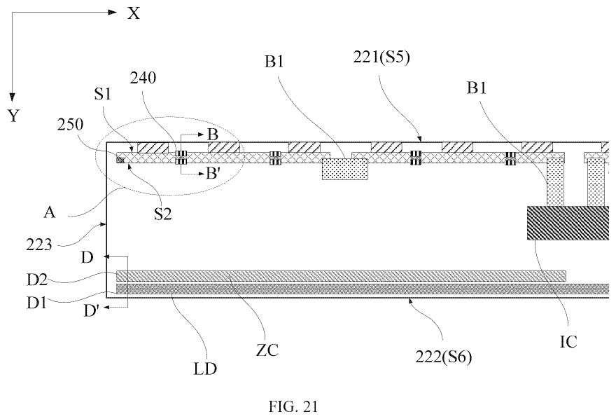

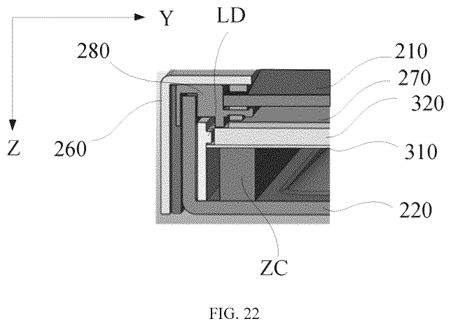

FIG. 21 schematically shows a schematic diagram of a light source assembly and support foam in embodiments of the present disclosure, and FIG. 22 schematically shows a cross-sectional view taken along section line DD′ in FIG. 21.

Referring to FIG. 21 and FIG. 22, in some specific embodiments, the backboard 220 includes a fifth side S5 and a sixth side S6 oppositely disposed in the second direction Y. The flexible clasper assembly 240 is located on the fifth side S5. The display module 200 further includes: a light source assembly LD and support foam ZC. The light source assembly LD is disposed on the sixth side S6 of the backboard 220, and the light source assembly LD extends in the first direction X. A light-emitting direction of the light source assembly LD intersects with the thickness direction Z of the display module 200. The light source assembly LD includes a first end D1 and a second end (not shown) oppositely disposed in the first direction X. The support foam ZC extends in the first direction X, and the support foam ZC includes a third end D2 and a fourth end oppositely disposed in the first direction X. The first end D1 is flush with the third end D2, and the second end is flush with the fourth end.

The fifth side S5 and the sixth side S6 of the backboard 220 may refer to two long sides of the backboard 220 that are oppositely disposed. For example, the fifth side S5 may be an upper side of the backboard 220 in FIG. 21, and the sixth side S6 may be a lower side of the backboard 220 in FIG. 21. The flexible clasper assembly 240 and the light source assembly LD are disposed on the upper side and the lower side, respectively. However, this does not constitute a limitation to embodiments of the present disclosure. The light source assembly LD may be disposed at any appropriate position on the backboard 220.

In embodiments of the present disclosure, the support foam ZC and the light source assembly LD may be disposed in parallel. An initial attachment position of the support foam ZC is as close as possible to a short side of the display module 200. For example, a left end (third end) of the support foam ZC in FIG. 21 is flush with a left end (first end) of the light source assembly LD. It may be understood that, FIG. 21 only shows a portion of the display module 200. In the other portion of the display module 200, a right end (fourth end) of the support foam ZC is also flush with a right end (second end) of the light source assembly LD, and for structures of the right end of the support foam ZC and the right end of the light source assembly LD, reference may be made to the left end of the support foam ZC and the left end of the light source assembly LD, which will not be repeated here.

After a reflective sheet 310 is formed, the support foam ZC may form a support at a corner of the reflective sheet 310 close to the light source assembly LD. In this way, the corner of the reflective sheet 310 may be effectively supported by the support foam ZC, thereby preventing the corner of the reflective sheet 310 from collapsing.

Optionally, a distance between the support foam ZC and its adjacent structure may be set in a range of 0.3 mm to 0.6 mm.

FIG. 23 schematically shows a schematic diagram of a reflective sheet exposed after shrinkage of a light guide plate in embodiments of the present disclosure.

Referring to FIG. 7, and FIG. 21 to FIG. 23, in some specific embodiments, the display module 200 further includes a light guide plate 320 and a reflective sheet 310. The reflective sheet 310 includes a third surface M3 and a fourth surface M4 oppositely disposed in a thickness direction of the reflective sheet 310. The third surface M3 is located on a side of the fourth surface M4 close to the light guide plate 320, and a second light-shielding structure 311 is provided on the third surface M3. The third surface M3 includes a seventh side S7 and an eighth side S8 oppositely disposed in the second direction Y. The eighth side S8 is located on a side of the seventh side S7 close to the light source assembly LD, and the second light-shielding structure 311 is located on the eighth side S8.

Referring to FIG. 7, the third surface M3 of the reflective sheet 310 may refer to an upper surface of the reflective sheet 310, and the fourth surface M4 of the reflective sheet 310 may refer to a lower surface of the reflective sheet 310. The seventh side S7 and the eighth side S8 may be two long sides of the reflective sheet 310 that are oppositely disposed. For example, the seventh side S7 may refer to an upper side of the reflective sheet 310 in FIG. 23, and the eighth side S8 of the reflective sheet 310 may refer to a lower side of the reflective sheet 310 in FIG. 23.

At −20° C., the light guide plate 320 and the reflective sheet 310 shrink, and a shrinkage degree of the light guide plate 320 is greater than a shrinkage degree of the reflective sheet 310, so that the reflective sheet 310 may be exposed by the light guide plate 320, which may cause light emitted by the light source assembly LD to directly irradiate the reflective sheet 310, resulting in poor display (e.g., light leakage). In embodiments of the present disclosure, the second light-shielding structure 311 may play a light-shielding role after the shrinkage of the light guide plate 320, thereby preventing part of the light from the light source assembly LD from directly irradiating the reflective sheet 310.

In some specific embodiments, a dimension of the second light-shielding structure 311 in the first direction X is set in a range of 1 mm to 3 mm, for example, the dimension of the second light-shielding structure 311 in the first direction X is set to 2 mm. A dimension of the second light-shielding structure 311 in the second direction is set in a range of 2 mm to 4 mm, for example, the dimension of the second light-shielding structure 311 in the first direction X is set to 3 mm. In this way, the second light-shielding structure 311 is located at two corners of the reflective sheet 310 close to the light source assembly LD. In this way, at −20° C., the second light-shielding structure 311 may cover a region of the reflective sheet 310 that is most severely irradiated by the light source assembly LD, while at a normal temperature (e.g., above 0° C.), the second light-shielding structure 311 only covers two corners of the reflective sheet 310, thereby reducing an impact of the second light-shielding structure 311 on a reflective area.

Optionally, the second light-shielding structure 311 may include a black ink coating or a black tape.

In some specific embodiments, the display module further includes a third light-shielding structure ZG, and the third light-shielding structure ZG is integrally connected with the second light-shielding structure 311. The backboard 220 includes a fifth surface M5 and a sixth surface M6 oppositely disposed in the thickness direction of the backboard 220. The fifth surface M5 is located on a side of the sixth surface M6 close to the display panel 210, and the third light-shielding structure ZG is located on the sixth surface M6.

Referring to FIG. 7, the fifth surface M5 of the backboard 220 may refer to an upper surface of the backboard 220, and the sixth surface M6 may refer to a lower surface of the backboard 220. At −20° C., the shrinkage of the light guide plate 320 may also cause the light emitted by the light source assembly LD to directly irradiate the backboard 220, resulting in poor display (e.g., light leakage caused by reflection of the backboard 220). In embodiments of the present disclosure, the third light-shielding structure ZG may improve stability of the second light-shielding structure 311 and prevent the second light-shielding structure 311 from falling off. At the same time, the third light-shielding structure ZG may also play a light-shielding role after the shrinkage of the light guide plate 320, thereby preventing part of the light from the light source assembly LD from directly irradiating the backboard 220.

In some specific embodiments, a dimension of the third light-shielding structure ZG in the first direction X is set in a range of 3 mm to 5 mm, such as 4 mm. In this way, at −20° C., the third light-shielding structure ZG may cover a region of the backboard 220 that is most severely irradiated by the light source assembly LD, thereby better improving a reflection problem.

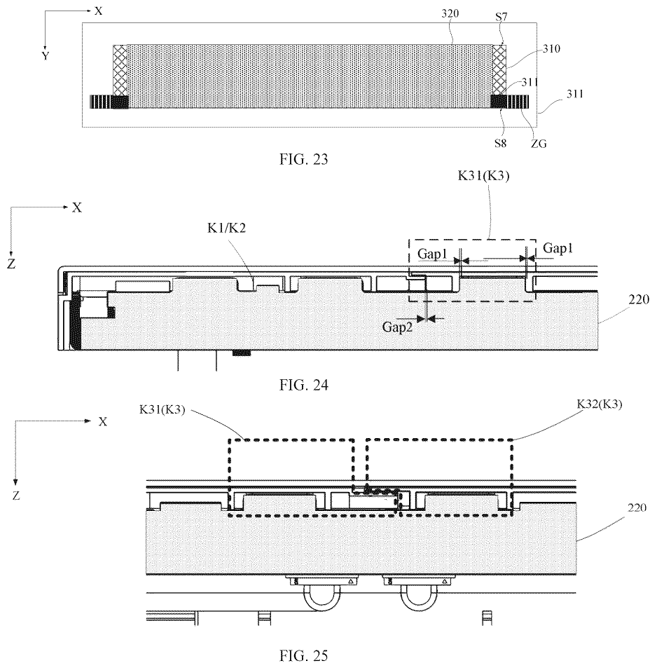

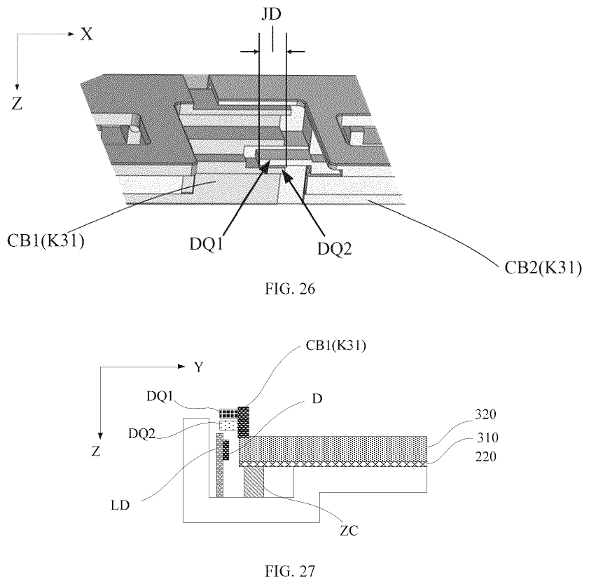

FIG. 24 schematically shows a cross-sectional view taken along section line EE′ in FIG. 5, FIG. 25 schematically shows a cross-sectional view taken along section line FF′ in FIG. 5, FIG. 26 schematically shows a schematic diagram of a barrier structure in embodiments of the present disclosure, and FIG. 27 schematically shows a schematic diagram of light shielding by a barrier in embodiments of the present disclosure.

Referring to FIG. 7, and FIG. 24 to FIG. 27, in some specific embodiments, the display module 200 includes the light source assembly LD and the plastic frame 280. The light source assembly LD includes a plurality of light-emitting devices D, and the plastic frame 280 includes a plurality of sub-frames. The plurality of sub-frames include a first sub-frame K1 and a second sub-frame K2 oppositely disposed in the first direction X, and a plurality of third sub-frames K3 located between the first sub-frame K1 and the second sub-frame K2. Each of the third sub-frames K3 includes a first splicing portion K31 and a second splicing portion K32 oppositely disposed in the first direction. The first splicing portion K31 of one of two adjacent third sub-frames K3 in the first direction X is spliced with the second splicing portion K32 of the other of the two adjacent third sub-frames K3 in the first direction X. The first splicing portion K31 includes a first sidewall CB1, and the second splicing portion includes a second sidewall CB2. Both the first sidewall CB1 and the second sidewall CB2 are located on a side of the light source assembly LD close to the center of the display module. A first barrier DQ1 is provided on a side of the first sidewall CB1 away from the center of the display module, and a second barrier DQ2 is provided on a side of the second sidewall CB2 away from the center of the display module. The first barrier DQ1 and the second barrier DQ2 overlap in the thickness direction of the display module, and an overlapping region overlaps at least one of the light-emitting devices D in the thickness direction Z of the display module.

The plurality of light-emitting devices D on the light source assembly LD are arranged in the first direction X. The first sub-frame K1 and the second sub-frame K2 may have a U-shaped structure, and the plurality of third sub-frames K3 are connected between the first sub-frame K1 and the second sub-frame K2, thereby forming an annular plastic frame 280. In other words, the plastic frame 280 is formed by splicing a plurality of sub-frames. In the first direction X, dimensions of the first sub-frame K1 and the second sub-frame K2 are smaller, while a dimension of the third sub-frame K3 is larger. In a wide-temperature environment, the third sub-frame K3 is easy to shrink. When the third sub-frame K3 shrinks, a large gap may be easily formed between two adjacent third sub-frames K3. Referring to FIG. 27, ideally, all the light emitted by the light-emitting device D enters the light guide plate 320. However, a light-emitting surface of the light-emitting device D is large, and part of the light emitted by the light-emitting device D exits upward. When a large gap is formed between two adjacent third sub-frames K3, the upwardly emitted light from the light-emitting device D may exit through the gap, resulting in a light leakage phenomenon.

Referring to FIG. 25, the third sub-frame K3 includes the first splicing portion K31 at a right end and the second splicing portion K32 at a left end. In FIG. 25, only a right end of a left third sub-frame K3 and a left end of a right third sub-frame K3 are shown. The left third sub-frame K3 is spliced with the second splicing portion K32 at the left end of the right third sub-frame K3 through the first splicing portion K31 at the right end of left third sub-frame K3.

Referring to FIG. 26, the first barrier DQ1 is provided on the first splicing portion K31, the second barrier DQ2 is provided on the second splicing portion K32, and the first barrier DQ1 and the second barrier DQ2 overlap in the thickness direction Z of the display module 200, so that the first barrier DQ1 and the second barrier DQ2 are staggered. In this way, even if the third sub-frame K3 shrinks, the upwardly emitted light from the light-emitting device D may be blocked by the staggered first barrier DQ1 and second barrier DQ2, thereby preventing an occurrence of light leakage.

In some specific embodiments, an overlapping region of the first barrier DQ1 and the second barrier DQ2 has a first design dimension JD in the first direction X, and the first design dimension JD is greater than or equal to 1 mm to 2.5 mm. In this way, the first design dimension is greater than or equal to a sum of a maximum shrinkage amounts (compared with those in normal temperature) of two adjacent third sub-frames K3 at −20° C. This may ensure that at −20° C., the first barrier DQ1 and the second barrier DQ2 may always block the upwardly emitted light from the light-emitting device D, thereby more effectively improving the light leakage problem.

In some specific embodiments, a precise positioning structure between the third sub-frame K3 and the backboard 220 is located on at least one of the first splicing portion K31 and the second splicing portion K32 of the third sub-frame K3. For example, the precise positioning structure is located on one of the first splicing portion K31 and the second splicing portion K32 that is away from the center of the display module 200. For example, the plastic frame 280 may include two third sub-frames K3 arranged in the first direction X, where the left third sub-frame K3 is adjacent to the first sub-frame K1, and the right third sub-frame K3 is adjacent to the second sub-frame K2. Accordingly, a precise positioning structure of the right third sub-frame K3 is located at a splicing position between the third sub-frame K3 and the second sub-frame K2, and a precise positioning structure of the left third sub-frame K3 is located at a splicing position between the third sub-frame K3 and the first sub-frame K1. The precise positioning structure may refer to a structure on the third sub-frame K3 that is used for matching and installation with the backboard 220. Optionally, all manufacturing tolerances and statistical tolerances may be accumulated at the splicing positions of adjacent sub-frames (e.g., between the first sub-frame K1 and the third sub-frame K3, between the second sub-frame K2 and the third sub-frame K3, or between two adjacent third sub-frames K3), thereby restricting a position where the third sub-frame K3 shrinks to the splicing position of the two adjacent third sub-frames K3. Furthermore, the light leakage problem caused by shrinkage may be intensively improved at the splicing position through the above-mentioned first barrier DQ1 and second barrier DQ2.

In embodiments of the present disclosure, a gap Gap1 between the precise positioning structure and the backboard 220 may be set to 0.1 mm, thereby minimizing a drift of a seam dimension caused by an assembly tolerance. A gap Gap2 between two adjacent third sub-frames K3 may be set to 0.2 mm, thereby minimizing a seam dimension.

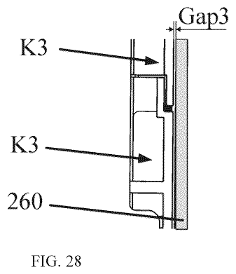

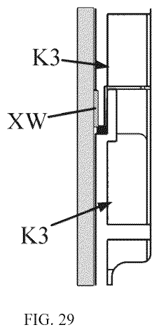

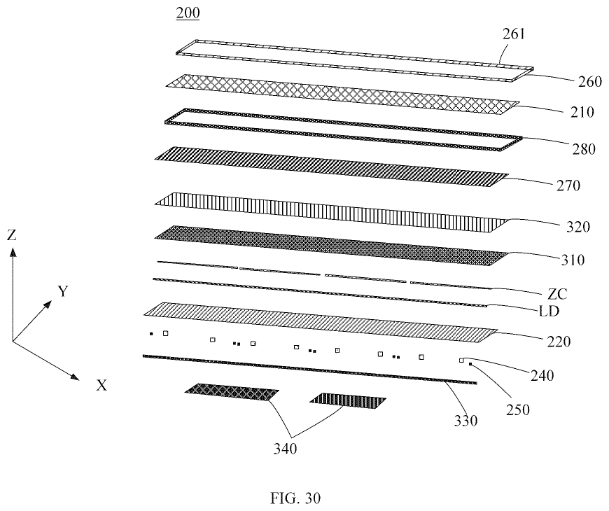

FIG. 28 schematically shows a schematic diagram of a gap between a third sub-frame and a front frame in embodiments of the present disclosure, and FIG. 29 schematically shows a schematic diagram of a limiting structure in embodiments of the present disclosure.

Referring to FIG. 28 and FIG. 29, in embodiments of the present disclosure, the display module 200 is a strip-shaped display module 200, and a length of its long side is much greater than a length of its short side. In the “vertical display” mode, at the splicing position of two adjacent third sub-frames K3, when a gap Gap3 (e.g., Gap3=0.2 mm) is provided between the third sub-frame K3 and the front frame 260, the upper third sub-frame K3 tends to shift toward the front frame 260. For example, the upper third sub-frame K3 tends to shift toward a right side in FIG. 28. This may easily lead to deviation of the third sub-frame K3 from a predetermined position, resulting in light leakage.

In view of this, in some specific embodiments, the display module 200 further includes a front frame 260. In an overlapping region of two adjacent third sub-frames K3, a limiting structure XW is filled in a gap between one of the two adjacent third sub-frames K3 and the front frame 260. The limiting structure XW may include an adhesive tape or a limiting rib, etc. Through the limiting structure XW, the third sub-frame K3 may be prevented from shifting toward the front frame 260, thereby limiting the third sub-frame K3 to a predetermined position and preventing light leakage.

By the above-mentioned method, embodiments of the present disclosure may solve the light leakage problem of the large-sized strip-shaped display module 200 in both the “horizontal display” mode and the “vertical display” mode under wide-temperature scenarios.

At the same time, in embodiments of the present disclosure, the plurality of sub-frames realize light shielding through the staggered barriers DQ. Even if the display module 200 reaches a high brightness (e.g., 1000 nits), no light leakage occurs, while a picture uniformity is good, for example, the picture uniformity may achieve 75%.

FIG. 30 schematically shows a second exploded view of a display module in embodiments of the present disclosure. Referring to FIG. 30, in some specific embodiments, the display module may further include a protective cover 330 of the first circuit board 230 and other circuit boards 340. The specific contents may be determined according to actual needs, which will not be limited here.

Embodiments of the present disclosure further provide a display device, including the above-mentioned display module 200.

Those skilled in the art will appreciate that various combinations and/or incorporations of features recited in various embodiments and/or claims of the present disclosure may be made, even if such combinations or incorporations are not explicitly recited in the present disclosure. In particular, without departing from the spirit and principles of the present disclosure, various combinations and/or incorporations of the features recited in the various embodiments and/or claims of the present disclosure may be made. All of the combinations and/or incorporations fall within the scope of the present disclosure.

Embodiments of the present disclosure have been described above. However, these embodiments are for illustrative purposes only, and are not used to limit the scope of the present disclosure. Although embodiments are described separately above, this does not mean that the measures in various embodiments may not be used advantageously in combination. The scope of the present disclosure is defined by the appended claims and their equivalents. Without departing from the spirit and principles of the present disclosure, those skilled in the art may make various substitutions and modifications, and these substitutions and modifications should all fall within the scope of the present disclosure.

1. A display module, comprising:
a display panel comprising a display region and a peripheral region at least partially surrounding the display region, wherein the peripheral region comprises a display binding pad;
a backboard disposed on a back side of the display panel;
a first circuit board disposed on a side of the backboard away from the display panel, wherein the first circuit board extends in a first direction, the first circuit board comprises a first side and a second side oppositely disposed in a second direction, the first side is electrically connected to the display binding pad, the second side is configured to be electrically connected to a display driver chip, and the first direction intersects with the second direction;
a flexible clasper assembly disposed on a side of the backboard away from the display panel, wherein the flexible clasper assembly comprises: a substrate, a first flexible clasper, and a second flexible clasper, the substrate is fixedly connected to the backboard, the first flexible clasper and the second flexible clasper are disposed on a side of the substrate away from the display panel, the first flexible clasper and the second flexible clasper are oppositely disposed in the second direction, and the first flexible clasper and the second flexible clasper are configured to clamp the first circuit board and allow a displacement of the first circuit board within a first preset range in the second direction; and
a conductive foam disposed on a side of the backboard away from the display panel, wherein at least one corner of the first circuit board is bonded to the backboard through the conductive foam, and the conductive foam allows a displacement of the first circuit board within a second preset range in the first direction.

2. The display module according to claim 1, wherein,
a portion of the first circuit board clamped by the first flexible clasper and the second flexible clasper comprises a first fixed portion;
in a thickness direction of the display module, the first flexible clasper overlaps with the first fixed portion, and an overlapping region of the first flexible clasper and the first fixed portion has a first dimension in the second direction;
in the thickness direction of the display module, the second flexible clasper overlaps with the first fixed portion, and an overlapping region of the second flexible clasper and the first fixed portion has a second dimension in the second direction; and
the first fixed portion has a third dimension in the second direction, and a ratio of a sum of the first dimension and the second dimension to the third dimension is greater than or equal to ⅓ and less than or equal to ½.

3. The display module according to claim 2, wherein the first dimension is set in a range of 3.5 mm to 4.5 mm, the second dimension is set in a range of 3.5 mm to 4.5 mm, and the third dimension is set in a range of 15 mm to 25 mm.

4. The display module according to claim 2, wherein,
the first flexible clasper comprises a first pressing portion and a first connecting portion, the first pressing portion is connected to the substrate through the first connecting portion, the second flexible clasper comprises a second pressing portion and a second connecting portion, the second pressing portion is connected to the substrate through the second connecting portion, and in the thickness direction of the display module, the first pressing portion and the second pressing portion overlap with the first fixed portion;
in the second direction, a first gap is provided between the first fixed portion and the first connecting portion, and a second gap is provided between the first fixed portion and the second connecting portion;
in the thickness direction of the display module, a third gap is provided between the first fixed portion and any one of the first pressing portion or the second pressing portion; and
any one of the first gap and the second gap is less than the third gap.

5. The display module according to claim 4, wherein the first gap is set in a range of 0.1 mm to 0.2 mm, the second gap is set in a range of 0.1 mm to 0.2 mm, and the third gap is set in a range of 0.15 mm to 0.25 mm.

6. The display module according to claim 1, wherein,
the first circuit board is electrically connected to the display binding pad through a plurality of chip-on-films, and the plurality of chip-on-films are arranged in the first direction;
the display module comprises a plurality of flexible clasper assemblies arranged in the first direction, at least one flexible clasper assembly is provided between at least two adjacent chip-on-films, wherein a distance between two adjacent flexible clasper assemblies in the first direction is set in a range of 250 mm to 350 mm; and
a dimension of the at least one flexible clasper assembly in the first direction is set in a range of 8 mm to 12 mm.

7. The display module according to claim 1, wherein,
the display module further comprises a front frame, the front frame comprises a first frame body extending in a thickness direction of the display module, and in the second direction, the first frame body is located on a side of the backboard away from a center of the display module;
in the second direction, a first distance is provided between the flexible clasper assembly and the first frame body, a second distance is provided between the backboard and the first frame body, and a third distance is provided between the display panel and the first frame body; and
the first distance is greater than the second distance and less than the third distance.

8. The display module according to claim 1, wherein,
the backboard comprises a backboard main body, and a first bending portion and a second bending portion disposed on the backboard main body, and the first bending portion and the second bending portion are bent toward the display panel and are oppositely disposed in the second direction;
in the second direction, the first circuit board is located between the first bending portion and the second bending portion, and a distance between the first bending portion and the first circuit board is less than a distance between the second bending portion and the first circuit board; and
in a thickness direction of the display module, the first flexible clasper overlaps with the first bending portion.

9. The display module according to claim 1, wherein the second side of the first circuit board comprises a first corner and a second corner oppositely disposed in the first direction, at least one of the first corner and the second corner comprises an exposed metal region, and the conductive foam at least partially covers the exposed metal region.

10. The display module according to claim 1, wherein a dimension of the conductive foam in the first direction is set in a range of 4 mm to 6 mm, a dimension of the conductive foam in the second direction is set in a range of 4 mm to 6 mm, and a thickness of the conductive foam is set in a range of 1 mm to 3 mm.

11. The display module according to claim 1, wherein,
the display module further comprises an optical film and a plastic frame, the optical film is disposed between the backboard and the display panel, the optical film comprises a third side and a fourth side oppositely disposed in the first direction, and a lug hole is provided on the third side;
the plastic frame comprises a second frame body extending in a thickness direction of the display module, and the second frame body is located on a side of the third side of the optical film away from a center of the optical film; and
the plastic frame further comprises a lug structure disposed on the second frame body, the lug structure extends toward the optical film, in the thickness direction of the display module, the lug structure overlaps with the lug hole, and in an overlapping region of the lug structure and the lug hole, the lug structure passes through the lug hole.

12. The display module according to claim 11, wherein,
a lug protrusion is further fixedly provided on the third side, the lug protrusion is located on a side of the lug hole away from the center of the optical film, and the display module further comprises an auxiliary fixing tape;
the backboard comprises a backboard main body, and a third bending portion and a fourth bending portion disposed on the backboard main body, and the third bending portion and the fourth bending portion are bent toward the display panel and are oppositely disposed in the first direction;
a side of the third bending portion away from a center of the display module is flush with the fourth side of the optical film; and
the auxiliary fixing tape comprises a winding portion and a first bonding portion, the winding portion passes through the lug hole and is wound around the lug protrusion, and the first bonding portion is bonded to the fourth bending portion.

13. The display module according to claim 12, wherein,
a first groove is provided on a side of the fourth bending portion close to the display panel, the first groove is recessed toward the backboard main body, and the lug protrusion is lapped in the first groove;
the second frame body is located on a side of the fourth bending portion away from the center of the display module; and the first bonding portion is bonded to a surface of the fourth bending portion facing the second frame body, and a gap is provided between the first bonding portion and the second frame body; and
the first bonding portion is bonded to two adjacent side surfaces of the fourth bending portion.

14. (canceled)

15. The display module according to claim 12, wherein, the auxiliary fixing tape further comprises an intermediate portion between the winding portion and the first bonding portion, and an end of the winding portion is bonded to the intermediate portion after bypassing an edge of the lug hole;
the fourth bending portion comprises a second groove recessed toward a side away from the second frame body, and the end of the winding portion is at least partially located in the second groove; and
a dimension of the first bonding portion in the second direction is greater than a dimension of the intermediate portion in the second direction, a transition corner is provided at a junction of the first bonding portion and the intermediate portion, and the transition corner comprises an arc-shaped corner.

16-17. (canceled)

18. The display module according to claim 11, wherein,
the optical film comprises a composite prism and a diffuser;
in the first direction, the diffuser comprises a first surface and a second surface oppositely disposed in a thickness direction of the diffuser, the first surface is located on a side of the second surface close to the composite prism, and a first light-shielding structure is provided on the first surface;
the first surface comprises a lug side and an opposite lug side oppositely disposed in the first direction, the lug hole is located on the lug side, and the first light-shielding structure is located on the opposite lug side;
a dimension of the first light-shielding structure in the first direction is set in a range of 2 mm to 4 mm; and
the first light-shielding structure comprises a black tape or a printed black border.

19-20. (canceled)

21. The display module according to claim 11, wherein the optical film comprises a single prism and a diffuser, the lug hole penetrates the single prism and the diffuser, and a thermal shrinkage rate of the single prism is the same as a thermal shrinkage rate of the diffuser.

22. The display module according to claim 1, wherein the backboard comprises a fifth side and a sixth side oppositely disposed in the second direction, the flexible clasper assembly is located on the fifth side, and the display module further comprises:
a light source assembly disposed on the sixth side of the backboard, wherein the light source assembly extends in the first direction, a light-emitting direction of the light source assembly intersects with a thickness direction of the display module, and the light source assembly comprises a first end and a second end oppositely disposed in the first direction;
a support foam extending in the first direction, wherein the support foam comprises a third end and a fourth end oppositely disposed in the first direction, the first end is flush with the third end, and the second end is flush with the fourth end; and
a light guide plate and a reflective sheet, wherein the reflective sheet comprises a third surface and a fourth surface oppositely disposed in a thickness direction of the reflective sheet, the third surface is located on a side of the fourth surface close to the light guide plate, and a second light-shielding structure is provided on the third surface, and wherein the third surface comprises a seventh side and an eighth side oppositely disposed in the second direction, the eighth side is located on a side of the seventh side close to the light source assembly, and the second light-shielding structure is located on the eighth side.

23. (canceled)

24. The display module according to claim 22, wherein,
a dimension of the second light-shielding structure in the first direction is set in a range of 1 mm to 3 mm, and a dimension of the second light-shielding structure in the second direction is set in a range of 2 mm to 4 mm;
the display module further comprises a third light-shielding structure, and the third light-shielding structure is integrally connected with the second light-shielding structure; the backboard comprises a fifth surface and a sixth surface oppositely disposed in a thickness direction of the backboard, the fifth surface is located on a side of the sixth surface close to the display panel, and the third light-shielding structure is located on the sixth surface; and
a dimension of the third light-shielding structure in the first direction is set in a range of 3 mm to 5 mm.

25-26. (canceled)

27. The display module according to claim 1, wherein,
the display module comprises a light source assembly and a plastic frame, the light source assembly comprises a plurality of light-emitting devices, the plastic frame comprises a plurality of sub-frames, and the plurality of sub-frames comprise a first sub-frame and a second sub-frame oppositely disposed in the first direction, and a plurality of third sub-frames located between the first sub-frame and the second sub-frame;
each of the third sub-frames comprises a first splicing portion and a second splicing portion oppositely disposed in the first direction, and the first splicing portion of one of two adjacent third sub-frames in the first direction is spliced with the second splicing portion of the other of the two adjacent third sub-frames in the first direction;
the first splicing portion comprises a first sidewall, the second splicing portion comprises a second sidewall, each of the first sidewall and the second sidewall is located on a side of the light source assembly close to a center of the display module, a first barrier is provided on a side of the first sidewall away from the center of the display module, and a second barrier is provided on a side of the second sidewall away from the center of the display module;
the first barrier and the second barrier overlap in a thickness direction of the display module, and an overlapping region of the first barrier and the second barrier overlaps with at least one of the light-emitting devices in the thickness direction of the display module;
the overlapping region of the first barrier and the second barrier has a first design dimension in the first direction, and the first design dimension is greater than or equal to 1 mm to 2.5 mm; and
the display module further comprises a front frame, and in an overlapping region of two adjacent third sub-frames, a limiting structure is filled in a gap between one of the two adjacent third sub-frames and the front frame.

28-29. (canceled)

30. A display device, comprising the display module according to claim 1.
